(19) United States
(12) Patent Application Publication
(10) Pub. No.: US 2024/0284769 A1
(43) Pub. Date: Aug. 22, 2024

(54) DISPLAY DEVICE

(71) Applicant: Samsung Display Co., Ltd., Yongin-si (KR)

(72) Inventor: MYUNGHWAN KIM, Yongin-si (KR)

(21) Appl. No.: 18/385,431

(22) Filed: Oct. 31, 2023

(30) Foreign Application Priority Data
Feb. 24, 2023 (KR) 10-2023-0025325

(51) Int. Cl. H10K 59/80; H10K 59/122; H10K 59/38

(52) U.S. Cl. CPC H10K 59/8792; H10K 59/122; H10K 59/38; H10K 59/872; H10K 59/8723; H10K 2102/311

(57) ABSTRACT

A display device includes: a display module; a window disposed on the display module; and a low reflection member disposed on the window and including a spacer and a nano-protrusion which have different cross-sectional shapes from each other, wherein a first thickness of the spacer is greater than or equal to a second thickness of the nano-protrusion, an upper surface of the spacer has a substantially flat surface that is parallel to an upper surface of the window, and a width of the nano-protrusion gradually reduces as a distance from the window increases.

### CROSS-REFERENCE TO RELATED APPLICATION

This US non-provisional patent application claims priority under 35 U.S.C. § 119 of Korean Patent Application No. 10-2023-0025325, filed on Feb. 24, 2023, the disclosure of which is incorporated by reference herein in its entirety.

### TECHNICAL FIELD

The present invention relates to a display device, and more particularly, to a display device including a low reflection member that reduces reflection of external light.

### DISCUSSION OF THE RELATED ART

Various display devices, which are used in multimedia devices, such as televisions, mobile phones, tablet computers, and game consoles, are under development. The display devices may be of a rigid type or a flexible type which may be variously changed in shape by being folded, rolled, or bent.

In these various types of display devices, optical members for increasing display quality have been used. However, when developing the optical members, it is desirable to ensure that the optical members exhibit excellent optical properties and, at the same time, have excellent durability and reliability according to the usage form of the display devices.

### SUMMARY

According to an embodiment of the present invention, a display device includes: a display module; a window disposed on the display module; and a low reflection member disposed on the window and including a spacer and a nano-protrusion which have different cross-sectional shapes from each other, wherein a first thickness of the spacer is greater than or equal to a second thickness of the nano-protrusion, an upper surface of the spacer has a substantially flat surface that is parallel to an upper surface of the window, and a width of the nano-protrusion gradually reduces as a distance from the window increases.

In an embodiment of the present invention, in a plan view parallel to the window, the spacer has an integrated shape in which a plurality of holes are provided.

In an embodiment of the present invention, the maximum width of each of the holes is about 1 micrometer (μm) to about 1000 micrometers (μm).

In an embodiment of the present invention, a plurality of nano-protrusions are arranged in each of the holes, and the plurality of nano-protrusions includes the nano-protrusion, and wherein upper portions of the plurality of nano-protrusions are spaced apart from each other.

In an embodiment of the present invention, each of the holes has a circular, elliptical, or polygonal shape.

In an embodiment of the present invention, distances between the upper portions of the plurality of nano-protrusions are about 30 nanometers (nm) to about 300 nanometers (nm).

In an embodiment of the present invention, the spacer includes a plurality of support protrusions spaced apart from each other, and a plurality of nano-protrusions are arranged between the support protrusions.

In an embodiment of the present invention, distances between the support protrusions are about 1 μm to about 1000 μm, and distances between the plurality of nano-protrusions are about 0.03 μm to about 0.3 μm.

In an embodiment of the present invention, the nano-protrusion has a cone shape, a polygonal pyramid shape having a polygonal lower surface, or a truncated cone shape.

In an embodiment of the present invention, the low reflection member further includes a base part disposed on the window.

In an embodiment of the present invention, the low reflection member includes a composite material that has organic resin and silicon oxide (SiOₓ), wherein the organic resin includes at least one of acrylate-based resin, urethane-based resin, or epoxy-based resin.

In an embodiment of the present invention, as a refractive index of the composite material increases, an area ratio of the upper surface of the spacer in the low reflection member is reduced.

In an embodiment of the present invention, the refractive index of the composite material is about 1.5 to about 1.6, and an area of the upper surface of the spacer is about 10% to about 45% on the basis of about 100% of the total area of the low reflection member.

In an embodiment of the present invention, the low reflection member further includes an antifouling additive that includes a fluorine-based additive or a silicone-based additive.

In an embodiment of the present invention, the low reflection member has a contact angle of about 95 degrees or more with respect to deionized water.

In an embodiment of the present invention, the low reflection member further includes a cover layer covering the spacer and the nano-protrusion and including the antifouling additive.

In an embodiment of the present invention, the display module includes: a display element layer including a pixel defining layer, in which a plurality of pixel openings are provided, and light emitting elements, which include light emitting layers respectively arranged in the pixel openings; a sensor layer disposed on the display element layer and including a conductive layer and an insulating layer; and a color filter layer disposed on the sensor layer and including a division pattern, in which division openings respectively corresponding to the pixel openings are provided, and filter parts, which are respectively arranged to overlap the division openings.

In an embodiment of the present invention, the display module includes: a display element layer including a pixel defining layer, in which a plurality of pixel openings are provided, light emitting elements, which include light emitting layers respectively arranged in the pixel openings, and an inorganic deposition layer, which is disposed on the light emitting elements; a sensor layer disposed on the display element layer and including a conductive layer and an insulating layer; and a light control layer disposed on the sensor layer and including pigment or dye.

In an embodiment of the present invention, the low reflection member is disposed directly on the window.

In an embodiment of the present invention, the display device further includes a folding region, a first non-folding region, and a second non-folding region, wherein the folding region is disposed between the first non-folding region and the second non-folding region.

According to an embodiment of the present invention, a display device includes: a display module; a window disposed on the display module; and a low reflection member disposed on the window and including a spacer, in which a plurality of holes are provided, and a plurality of nano-protrusions, which are respectively arranged in the holes, wherein an upper surface of the spacer, which is spaced apart from the window, has a substantially flat surface, a width of each of the nano-protrusions is gradually reduced in a direction away from the window, and the spacer has a first thickness, and each of the nano-protrusions has a second thickness that is greater than or equal to half of the first thickness and less than or equal to the first thickness.

In an embodiment of the present invention, the maximum width of each of the holes is about 1 micrometer (μm) to about 1000 micrometers (μm).

In an embodiment of the present invention, each of the holes has a circular, elliptical, or polygonal shape.

In an embodiment of the present invention, upper portions of the nano-protrusions are spaced apart from each other at a distance of about 30 nanometers (nm) to about 300 nanometers (nm).

In an embodiment of the present invention, the low reflection member includes a composite material that has organic resin and silicon oxide (SiOₓ), wherein the organic resin includes at least one of acrylate-based resin, urethane-based resin, or epoxy-based resin.

In an embodiment of the present invention, as a refractive index of the composite material increases, an area ratio of the upper surface of the spacer in the low reflection member is reduced.

In an embodiment of the present invention, the refractive index of the composite material is about 1.5 to about 1.6, and an area of the upper surface of the spacer is about 10% to about 45% on the basis of about 100% of the total area of the low reflection member.

### BRIEF DESCRIPTION OF THE DRAWINGS

The above and other features of the present invention will become apparent by describing in detail embodiments thereof with reference to the accompanying drawings, in which:

FIG. 1A is a perspective view of an unfolded state of a display device according to an embodiment of the present invention;

FIG. 1B is a perspective view showing a folding operation of a display device according to an embodiment of the present invention;

FIG. 1C is a perspective view showing a folding operation of a display device according to an embodiment of the present invention;

FIG. 2 is an exploded perspective view of a display device according to an embodiment of the present invention;

FIG. 3A is a cross-sectional view of a display module according to an embodiment of the present invention;

FIG. 3B is a cross-sectional view of a display module according to an embodiment of the present invention;

FIG. 4 is a plan view of a low reflection member according to an embodiment of the present invention;

FIG. 5A is a cross-sectional view of a low reflection member according to an embodiment of the present invention;

FIG. 5B is a cross-sectional view of a low reflection member according to an embodiment of the present invention;

Each of FIGS. 6A, 6B and 6C is a perspective view of a nano-protrusion according to an embodiment of the present invention;

FIG. 7A is a plan view of a low reflection member according to an embodiment of the present invention;

FIG. 7B is a plan view of a low reflection member according to an embodiment of the present invention;

FIG. 8A is a perspective view of a low reflection member according to an embodiment of the present invention;

FIG. 8B is a plan view of a low reflection member according to an embodiment of the present invention;

FIG. 9 is a cross-sectional view of a low reflection member according to an embodiment of the present invention;

FIG. 10A is a graph showing reflectance according to a viewing angle, and

FIG. 10B is a graph showing reflectance according to a wavelength.

### DETAILED DESCRIPTION OF THE EMBODIMENTS

Since the present invention may have various modifications and be embodied in different forms, specific embodiments are illustrated in the drawings and described in detail in the description. However, the disclosed embodiments are not intended to limit the present invention to the specific embodiments, and it should be understood that the present disclosure covers all the modifications, equivalents, and replacements within the idea and technical scope of the present invention.

In the specification, it will be understood that when an element (or a region, a layer, a portion, or the like) is referred to as being “on,” “connected to,” or “coupled to” another element, it can be directly disposed on, connected to, or coupled to another element mentioned above, or intervening elements may be disposed therebetween.

However, in the present application, being “disposed directly on” may mean that there is no additional layer, film, region, plate, or the like between a part and another part such as a layer, a film, a region, or a plate. For example, being “disposed directly on” may mean that two layers or two members are disposed without using an additional member such as an adhesive member therebetween.

Like numbers refer to like elements throughout the specification and the drawings. In addition, various thicknesses, lengths, and angles are shown and while the arrangement shown does indeed represent an embodiment of the present disclosure, it is to be understood that modifications of the various thicknesses, lengths, and angles may be possible within the spirit and scope of the present disclosure and the present disclosure is not necessarily limited to the particular thicknesses, lengths, and angles shown. The term “and/or” includes any and all combinations of one or more of the associated listed items.

Although the terms “first,” “second,” etc. may be used herein to describe various elements, these elements should not be limited by these terms. These terms are only used to distinguish one element from another element. For example, a first element may be referred to as a second element, and similarly, a second element may also be referred to as a first element without departing from the scope of the present disclosure. The singular forms include the plural forms as well, unless the context clearly indicates otherwise.

Also, terms such as “below,” “lower,” “above,” and “upper” may be used to describe the relationships of the components illustrated in the drawings. These terms are used as a spatially relative concept and are described based on the directions indicated in the drawings. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly. In the specification, being “disposed on” may represent not only being disposed on the top surface but also being disposed on the bottom surface.

Hereinafter, a display device according to an embodiment of the present invention is described below with reference to the drawings.

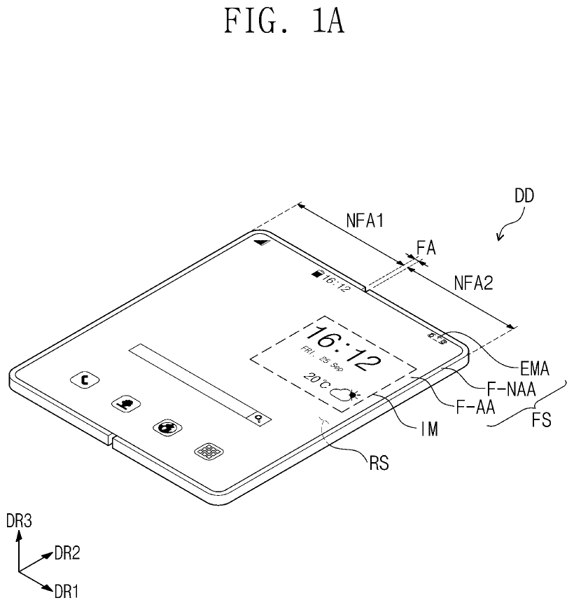

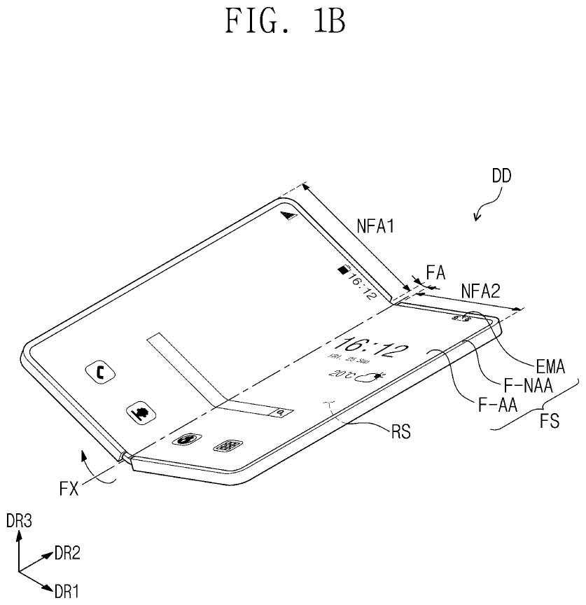

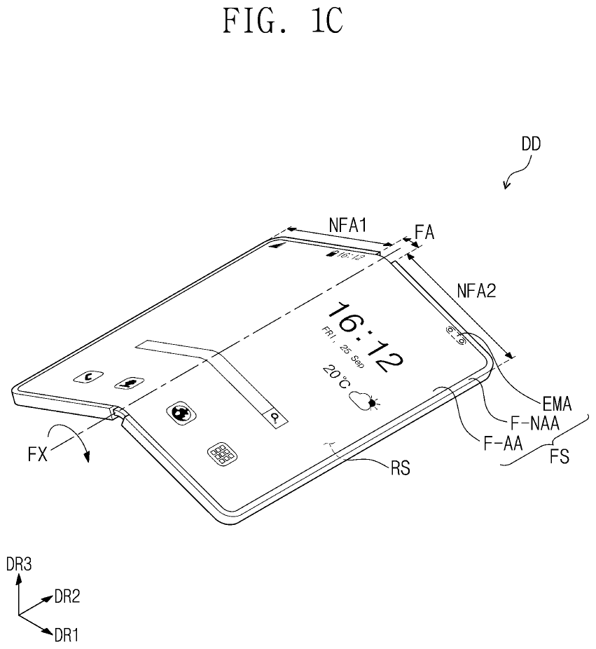

FIG. 1A is a perspective view showing an unfolded state of a display device according to an embodiment of the present invention. FIG. 1B is a perspective view showing an in-folding operation of the display device illustrated in FIG. 1A. FIG. 1C is a perspective view showing an out-folding operation of the display device illustrated in FIG. 1A.

A display device DD according to an embodiment of the present invention may include a device that is activated in response to an electrical signal. For example, the display device DD may include a mobile phone, a tablet PC, a vehicle navigation unit, a game console, or a wearable device, but the embodiment is not limited thereto. In FIG. 1A, etc. of the specification, the display device DD is illustratively shown as a mobile phone.

Referring to FIGS. 1A to 1C, the display device DD according to an embodiment of the present invention may include a first display surface FS that is defined by a first direction axis DR1 and a second direction axis DR2 crossing the first direction axis DR1. The display device DD may provide a user with an image MI via the first display surface FS. The display device DD according to an embodiment of the present invention may display the image IM, in a third direction axis DR3, via the first display surface FS parallel to both the first direction axis DR1 and the second direction axis DR2. As used herein, a front surface (or an upper surface) and a rear surface (or a lower surface) of each component are defined on the basis of the direction in which the image IM is displayed. The front and rear surfaces are opposed to each other in the third direction axis DR3, and the normal direction of each of the front and rear surfaces may be parallel to the third direction axis DR3.

The display device DD according to an embodiment of the present invention may sense an external input applied from the outside. The external input may include various types of inputs provided from the outside of the display device DD. For example, the external input may include a touch by a part of the user's body, such as a hand, and include an external input (for example, hovering) applied when approaching the display device DD or brought close thereto within a certain distance. Also, various types, such as force, pressure, temperature, and light, are possible.

Here, the first direction axis DR1 to the third direction axis DR3 are illustrated in FIG. 1A and the following drawings. The directions indicated as the first to third direction axes DR1, DR2, and DR3 illustrated herein may have a relative concept and thus be changed to other directions. The directions indicated as the first to third direction axes DR1, DR2, and DR3 may be referred to as first to third directions, and the same reference symbols may be used.

The display device DD according to an embodiment of the present invention may include a first display surface FS and a second display surface RS. The first display surface FS may include an active region F-AA, a peripheral region F-NAA, and an electronic module region EMA. In an embodiment of the present invention, the electronic module region EMA may be included in the active region F-AA. The second display surface RS may be defined as a surface which is opposed to at least a portion of the first display surface FS. For example, the second display surface RS may be a portion of the rear surface of the display device DD.

The active region F-AA of the display device DD may include a region activated in response to an electrical signal. The display device DD according to an embodiment of the present invention may display the image IM via the active region F-AA. In addition, the active region F-AA may sense various types of external inputs.

The peripheral region F-NAA is adjacent to the active region F-AA. The peripheral region F-NAA may have a certain color. The peripheral region F-NAA may at least partially surround the active region F-AA. Accordingly, the shape of the active region F-AA may be substantially defined by the peripheral region F-NAA. However, this is merely illustrated as an example, and for example, the peripheral region F-NAA may be located adjacent to only one side of the active region F-AA or omitted. The display device DD according to an embodiment of the present invention may include active regions having various shapes, and is not limited to one embodiment.

Various electronic modules may be arranged in the electronic module region EMA. For example, the electronic module may include at least one of a camera, a speaker, a light detection sensor, or a heat detection sensor. The electronic module region EMA may sense an external object received via the first and second display surfaces FS and RS or may provide a sound signal, such as voice, to the outside via the first and second display surfaces FS and RS. The electronic modules may include a plurality of components, and are not limited to one specific embodiment.

In FIG. 1A, etc., the electronic module region EMA is illustrated as being located inside the active region F-AA, but the embodiment is not limited thereto. For example, the electronic module region EMA may be surrounded by the active region F-AA and the peripheral region F-NAA, or the electronic module region EMA may be surrounded by the peripheral region F-NAA.

The display device DD may include at least one folding region. The display device DD according to an embodiment of the present invention may include a folding region FA and non-folding regions NFA1 and NFA2. In an embodiment of the present invention, the non-folding regions NFA1 and NFA2 may be arranged adjacent to the folding region FA with the folding region FA therebetween. The display device DD according to an embodiment of the present invention may include a first non-folding region NFA1 and a second non-folding region NFA2 which are spaced apart from each other in the first direction axis DR1 with the folding region FA disposed therebetween. For example, the first non-folding region NFA1 may be located on one side of the folding region FA in the first direction DR1, and the second non-folding region NFA2 may be located on the other side of the folding region FA in the first direction DR1.

In the display device DD in a folded state, the radius of curvature of the folding region FA may be about 1.5 mm or less. For example, in a structure in which the first non-folding region NFA1 and the second non-folding region NFA2 face each other in the display device DD when folded according to an embodiment of the present invention, the radius of curvature of the folding region FA may be about 1.0 mm or less.

Here, although FIGS. 1A to 1C illustrate an embodiment in which the display device DD includes one folding region FA, the embodiment of the present invention is not limited thereto. A plurality of folding regions may be provided in the display device DD. For example, the display device DD according to an embodiment of the present invention includes two or more folding regions and three or more non-folding regions arranged with each of the folding regions therebetween.

Referring to FIG. 1B, the display device DD according to an embodiment of the present invention may be folded about a folding axis FX. The folding axis FX is a virtual axis extending in the second direction axis DR2, and the folding axis FX may be parallel to a direction of a long side of the display device DD. The folding axis FX may extend, on the first display surface FS, in the second direction axis DR2.

The display device DD may be folded about the folding axis FX and transformed into an in-folding state. In this state, one region of the first display surface FS, which overlaps the first non-folding region NFA1, and the other region thereof, which overlaps the second non-folding region NFA2, face each other.

Here, in the in-folding state of the display device DD according to an embodiment of the present invention, the second display surface RS may be viewed by a user. The second display surface RS may further include an electronic module region in which electronic modules including various components are arranged, but is not limited to any one specific embodiment.

Referring to FIG. 1C, the display device DD according to an embodiment of the present invention may be folded about the folding axis FX and transformed into an out-folding state. In this state, one region of the second display surface RS, which overlaps the first non-folding region NFA1, and the other region thereof, which overlaps the second non-folding region NFA2, face each other.

However, the present invention is not limited thereto, and portions of each of the first display surface FS and the second display surface RS may face each other by folding about a plurality of folding axes. The number of folding axes and the number of non-folding regions corresponding thereto are not particularly limited.

The shape of the display device according to an embodiment of the present invention is not limited to those illustrated in FIGS. 1A to 1C. The display device according to an embodiment may include a foldable display device that includes a folding region folded about a folding axis parallel to a short side of the display device. In addition, the display device according to an embodiment of the present invention may be of a rigid type that does not include a folding region.

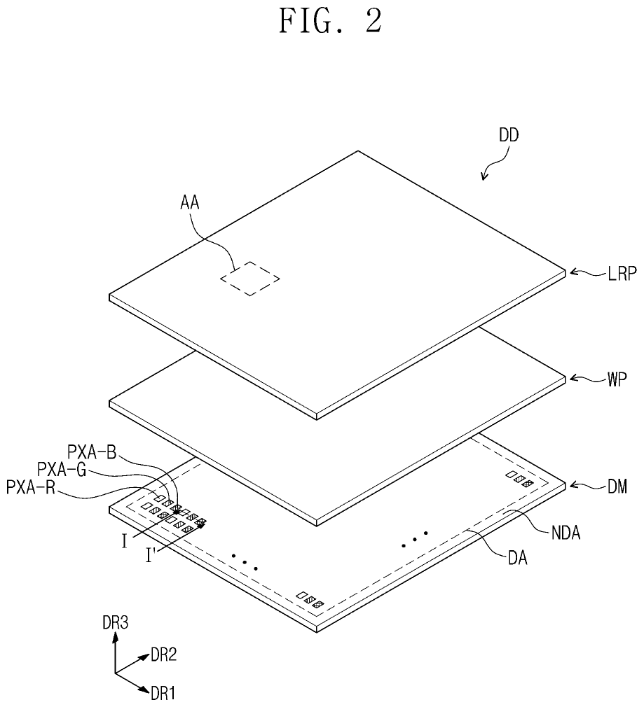

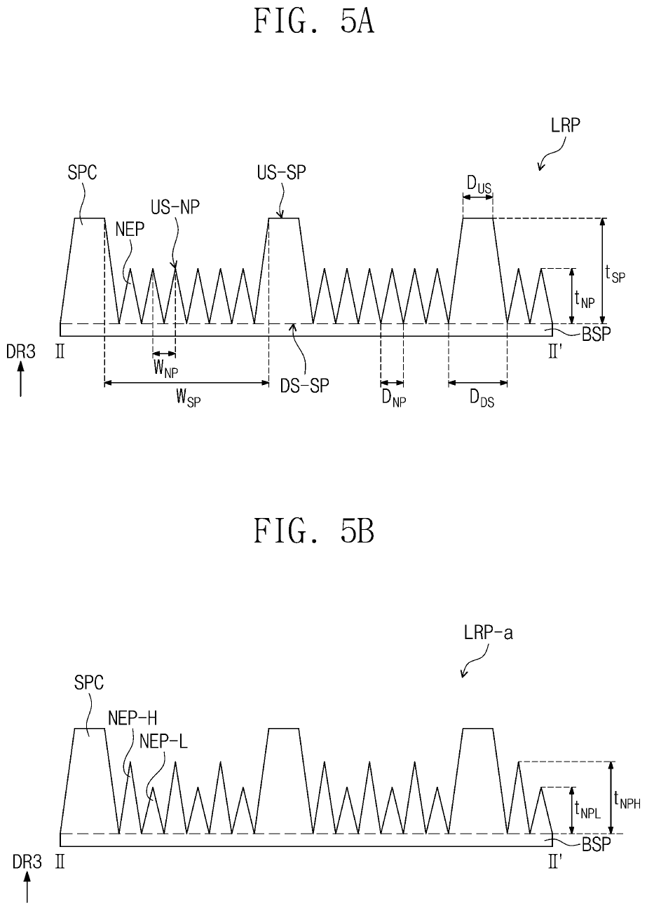

FIG. 2 is an exploded perspective view of a display device according to an embodiment of the present invention. The display device DD according to an embodiment of the present invention may include a display module DM, a window WP, and a low reflection member LRP which are sequentially stacked on each other in the third direction axis DR3. An adhesive layer may be located at least one of between the display module DM and the window WP or between the window WP and the low reflection member LRP. When the adhesive layer is not provided between the window WP and the low reflection member LRP, the low reflection member LRP may be directly disposed on the upper surface of the window WP. For example, lower surfaces of a spacer SPC (FIG. 5A) and a nano-protrusion N-EP (FIG. 5A) of the low reflection member LRP, which are described below, may be arranged adjacent to the upper surface of the window WP. In addition, in an embodiment of the present invention, a base part BSP (FIG. 5A) of the low reflection member LR-P, which is described below, may be directly disposed on the upper surface of the window WP.

The display device according to an embodiment of the present invention includes the low reflection member LRP disposed above the display module DM, and thus, may exhibit optical characteristics of reduced reflectance, thereby achieving increased display quality.

The display module DM may display an image in response to an electrical signal and transmit/receive information about an external input. The display module DM may include a display region DA and a non-display region NDA. The display region DA may be a region through which an image provided from the display module DM is emitted.

The non-display region NDA is adjacent to the display region DA. For example, the non-display region NDA may at least partially surround the display region DA. However, this is merely illustrated as an example. The non-display region NDA may have various shapes and is not limited to any one embodiment. According to an embodiment of the present invention, the display region DA of the display module DM may correspond to at least a portion of the active region F-AA (FIG. 1A).

The display module DM may include a plurality of pixels. The display region DA of the display module DM may include a plurality of pixel regions PXA-R, PXA-G, and PXA-B. The plurality of pixel regions PXA-R, PXA-G, and PXA-B may be arranged repeatedly in the display region DA.

The display module DM may include a first pixel region PXA-R, a second pixel region PXA-G, and a third pixel region PXA-B, which emit light of different wavelength ranges from each other. For example, the first pixel region PXA-R may include a red light emitting region that emits red light, the second pixel region PXA-G may include a green light emitting region that emits green light, and the third pixel region PXA-B may include a blue light emitting region that emits blue light. Here, the embodiment is not limited thereto, and the plurality of pixel regions may include combinations of pixel regions that emit colors other than the red, green, and blue colors described above. In addition, one pixel region may be provided in plurality unlike other pixel regions, and a white light emitting region that emits white light may be further provided in addition to the three pixel regions.

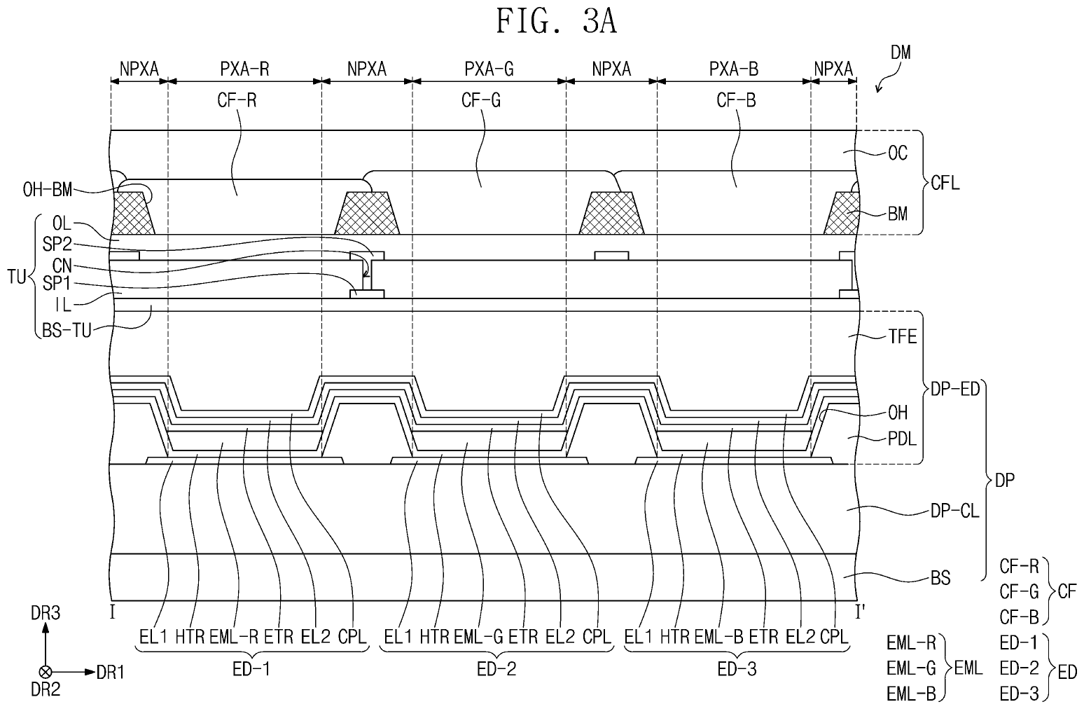

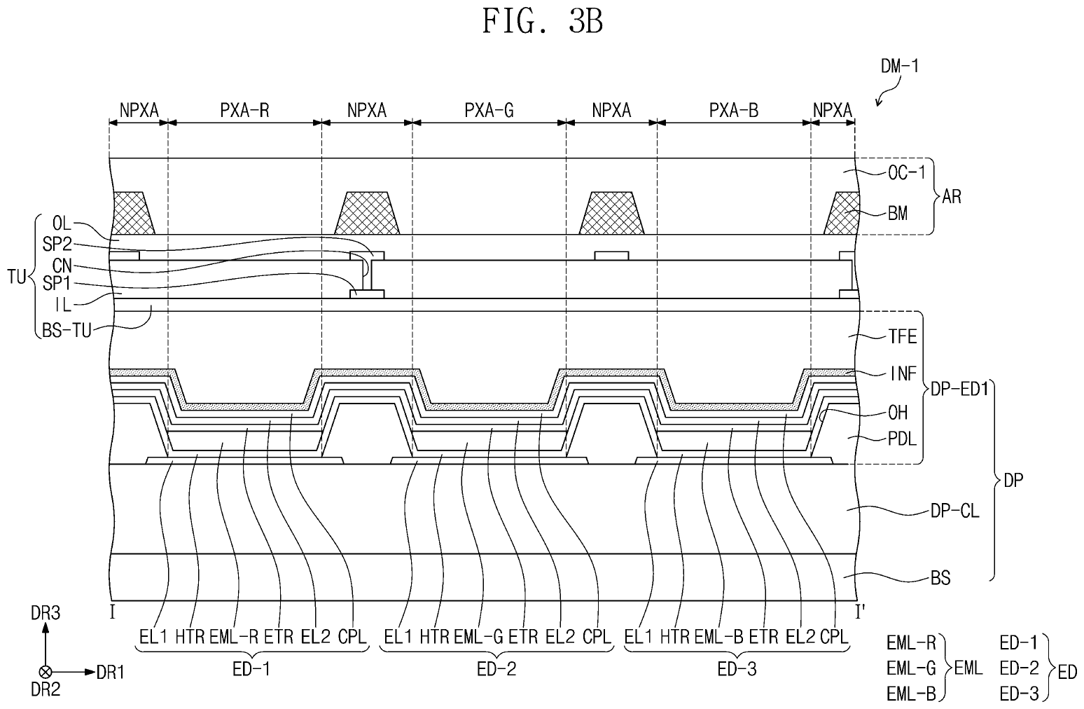

When viewed in a plan view defined by the first direction axis DR1 and the second direction axis DR2, the first to third pixel regions PXA-R, PXA-G, and PXA-B might not vertically overlap each other but are distinguished from each other. The display region DA of the display module DM may include a light blocking region NPXA. The light blocking region NPXA may be located around the pixel regions PXA-R, PXA-G, and PXA-B, and the light blocking region NPXA sets boundaries between the pixel regions PXA-R, PXA-G, and PXA-B. The light blocking region NPXA may surround each of the first to third pixel regions PXA-R, PXA-G, and PXA-B. A structure for preventing color mixing between the first to third pixel regions PXA-R, PXA-G, and PXA-B, for example, a pixel defining layer PDL (FIGS. 3A and 3B) or a division pattern BM (FIGS. 3A and 3B), may be correspondingly arranged in the light blocking region NPXA.

The pixel regions PXA-R, PXA-G, and PXA-B of the display device DD according to an embodiment of the present invention may be arranged in a stripe shape. Referring to FIG. 2, a plurality of first pixel regions PXA-R, a plurality of second pixel regions PXA-G, or a plurality of third pixel regions PXA-B may be arranged in the second direction DR2. In addition, the first pixel regions PXA-R, the second pixel regions PXA-G, and the third pixel regions PXA-B may be alternately and repeatedly arranged in this order in the first direction DR1.

In FIG. 2, etc., all of the pixel regions PXA-R, PXA-G, and PXA-B are illustrated as having similar areas. However, the embodiment is not limited thereto, and areas of the pixel regions PXA-R, PXA-G, and PXA-B may be different from each other depending on wavelength ranges of the emitted light. In addition, the area of each of the pixel regions PXA-R, PXA-G, and PXA-B may represent the area when viewed in a plan view defined by the first and second directions DR1 and DR2.

In addition, the arrangement of the pixel regions PXA-R, PXA-G, and PXA-B is not limited to that illustrated in FIG. 2. The order, in which the red pixel region PXA-R, the green pixel region PXA-G, and the blue pixel region PXA-B are arranged, may be variously combined depending on characteristics of display qualities in the display device DD. For example, the arrangement of the pixel regions PXA-R, PXA-G, and PXA-B may have a pentile arrangement or a diamond pixel arrangement.

In addition, the pixel regions PXA-R, PXA-G, and PXA-B may have different areas. For example, in an embodiment of the present invention, the area of the green pixel region PXA-G may be smaller than the area of the blue pixel region PXA-B, but the embodiment is not limited thereto.

The window WP may be disposed on the display module DM and cover the upper surface of the display module DM. For example, window WP may cover the entire upper surface of the display module DM. The window WP may have a shape conforming to the shape of the display module DM. The window WP may include, for example, a substrate or a film that includes glass or a polymer material. In addition, the window WP may further include a functional layer, such as a protective film, or an optical film layer disposed on the upper side of the substrate or film serving as a base.

The display device DD according to an embodiment of the present invention may include a low reflection member LRP disposed on the window WP. The low reflection member LRP may reduce reflected light of the display device DD generated by external light. The low reflection member LRP may include a reflection-preventing layer that reduces reflectance of external light that is incident from the outside of the display device DD.

The low reflection member LRP may have light transmittance of about 90% or more in a visible light range. For example, the low reflection member LRP may have light transmittance of about 95% or more in the visible light range. The display device DD including the low reflection member LRP disposed above the display module DM, according to an embodiment of the present invention, may exhibit reflectance of about 3% or less in the visible light range. The low reflection member according to an embodiment of the present invention is described below in more detail.

Each of FIGS. 3A and 3B is a cross-sectional view of a display module according to an embodiment of the present invention. Each of FIGS. 3A and 3B may be a cross-sectional view of a display module corresponding to line I-I′ of FIG. 2.

Referring to FIG. 3A, a display module DM according to an embodiment of the present invention may include a display panel DP, a sensor layer TU disposed on the display panel DP, and a color filter layer CFL disposed on the sensor layer TU.

The display panel DP according to an embodiment of the present invention may include a self-emissive display panel. For example, the display panel DP may include a micro LED display panel, a nano LED display panel, an organic light emitting display panel, or a quantum-dot light emitting display panel. However, this is merely an example, and the embodiment is not limited thereto as long as the display panel includes a self-emissive display panel.

A light emitting layer of the organic light emitting display panel may include an organic light emitting material. A light emitting layer of the quantum-dot light emitting display panel may include quantum dots and/or quantum rods. The micro LED display panel may include a micro light emitting diode element, which is a subminiature light emitting element, and the nano LED display panel may include a nano light emitting diode element. Hereinafter, the display panel DP is described as the organic light emitting display panel.

The display panel DP may include a base layer BS, a circuit layer DP-CL, and a display element layer DP-ED, which are sequentially stacked on each other. The display element layer DP-ED may include a pixel defining layer PDL, light emitting elements ED, which include light emitting layers EMIL respectively arranged in a plurality of pixel openings OH defined in the pixel defining layer PDL, and an encapsulation layer TFE disposed on the light emitting elements ED.

In the display panel DP, the base layer BS may include a member that provides a base surface on which the display element layer DP-ED is disposed. The base layer BS may be rigid or flexible. The base layer BS may be, for example, a glass substrate, a metal substrate, a polymer substrate, or the like. However, the embodiment is not limited thereto, and the base layer BS may include, for example, an inorganic layer, an organic layer, or a composite material layer.

The base layer BS may have not only a single-layer structure but also a multi-layer structure. For example, the base layer BS may have a three layer structure of, for example, a polymer resin layer, an adhesive layer, and a polymer resin layer. For example, the polymer resin layer may include polyimide-based resin. In addition, the polymer resin layer may include at least one of, for example, an acrylate-based resin, a vinyl-based resin, an epoxy-based resin, a urethane-based resin, a cellulose-based resin, a siloxane-based resin, and/or a perylene-based resin. In addition, as used herein, a “-based” resin may be regarded as including a “-” functional group.

The circuit layer DP-CL may be disposed on the base layer BS. The circuit layer DP-CL may include an insulating layer, a semiconductor pattern, a conductive pattern, a signal line, and the like. The circuit layer DP-CL may include a plurality of transistors which include semiconductor patterns, conductive patterns, and signal lines. Each of the transistors may include a control electrode, an input electrode, and an output electrode. For example, the circuit layer DP-CL may include switching transistors and driving transistors for driving the light emitting elements ED.

The display element layer DP-ED may be disposed on the circuit layer DP-CL. The display element layer DP-ED may include a pixel defining layer PDL, a light emitting element ED, and an encapsulation layer TFE. In an embodiment of the present invention, the display element layer DP-ED may include a plurality of light emitting elements ED-1, ED-2, and ED-3.

Each of the light emitting elements ED-1, ED-2, and ED-3 may include a first electrode EL1, a second electrode EL2 facing the first electrode EL1, and a light emitting layer EML located between the first electrode EL1 and the second electrode EL2. Each of the light emitting elements ED-1, ED-2, and ED-3 may include a hole transport region HTR and an electron transport region ETR. Each of the light emitting elements ED-1, ED-2, and ED-3 may include a capping layer CPL disposed on the second electrode EL2.

In the display element layer DP-ED, a first light emitting element ED-1 may include a first light emitting layer EML-R overlapping the first pixel region PXA-R, and a second light emitting element ED-2 may include a second light emitting layer EML-G overlapping the second pixel region PXA-G. A third light emitting element ED-3 may include a third light emitting layer EML-B overlapping the third pixel region PXA-B.

The pixel defining layer PDL may be disposed on the circuit layer DP-CL. A plurality of pixel openings OH may be defined in the pixel defining layer PDL. At least a portion of the first electrode EL1 may be exposed in the pixel openings OH of the pixel defining layer PDL.

The pixel openings OH formed in the pixel defining layer PDL may respectively correspond to the pixel regions PXA-R, PXA-G, and PXA-B. The light blocking region NPXA is a region between the neighboring pixel regions PXA-R, PXA-G, and PXA-B and may be a region corresponding to the pixel defining layer PDL.

The pixel defining layer PDL may include organic resin or an inorganic material. For example, the pixel defining layer PDL may include polyacrylate-based resin, polyimide-based resin, silicon nitride (SiNₓ), silicon oxide (SiOₓ), silicon oxynitride (SiOₓN_{y}), or the like.

In addition, in an embodiment of the present invention, the pixel defining layer PDL may have a feature of absorbing light and, for example, may have black color. The pixel defining layer PDL may include a black coloring agent. The black coloring agent may include black dye or black pigment. The pixel defining layer PDL may correspond to a light blocking pattern that has light blocking characteristics.

FIGS. 3A and 3B illustrate an embodiment of the present invention in which the light emitting layers EML-R, EML-B, and EML-G of the light emitting elements ED-1, ED-2, and ED-3 are arranged in the pixel openings OH formed in the pixel defining layer PDL. In addition, in this embodiment, the hole transport region HTR, the electron transport region ETR, the second electrode EL2, and the capping layer CPL are provided as a common layer over all of the light emitting elements ED-1, ED-2, and ED-3. However, the embodiment is not limited thereto. In an embodiment of the present invention different from that illustrated in FIGS. 3A and 3B, at least one of the hole transport region HTR, the electron transport region ETR, the second electrode EL2, and/or the capping layer CPL may be patterned and provided in the pixel openings OH formed in the pixel defining layer PDL.

In an embodiment of the present invention, at least one of the hole transport region HTR, the light emitting layers EML-R, EML-G, and EML-B, the electron transport region ETR, the second electrode EL2, and/or the capping layer CPL of the light emitting elements ED-1, ED-2 and ED-3 may be patterned and provided through an inkjet printing method.

In a light emitting element ED, the first electrode EL1 may be disposed on the circuit layer DP-CL. The first electrode EL1 may include an anode or a cathode. In addition, the first electrode EL1 may include a pixel electrode. The first electrode EL1 may include a transmissive electrode, a transflective electrode, or a reflective electrode.

The hole transport region HTR may be located between the first electrode EL1 and the light emitting layer EML. The hole transport region HR may include at least one of a hole injection layer, a hole transport layer, and/or an electron blocking layer. The hole transport region HTR may be provided as a common layer to overlap all of the pixel regions PXA-R, PXA-G, and PXA-B and the pixel defining layer PDL that divides the pixel regions PXA-R, PXA-G, and PXA-B. However, the embodiment is not limited thereto. For example, the hole transport region HTR may be patterned so that the hole transport region HTR are separated from each other to respectively correspond to the pixel regions PXA-R, PXA-G, and PXA-B.

The light emitting layer EML may be disposed on the first electrode EL1. The light emitting layer EML may include a plurality of light emitting layers EML-R, EML-G, and EML-B. A first light emitting layer EML-R may overlap the first pixel region PXA-R and emit first light. A second light emitting layer EML-G may overlap the second pixel region PXA-G and emit second light. A third light emitting layer EML-B may overlap the third pixel region PXA-B and emit third light. In the light emitting elements ED-1, ED-2, and ED-3 according to an embodiment of the present invention, the first to third lights may have substantially different wavelength ranges from each other. For example, the first light may include red light in a wavelength range of about 625 nm to about 675 nm, and the second light may include green light in a wavelength range of about 500 nm to about 570 nm. The third light may include blue light in a wavelength range of about 410 nm to about 480 nm.

The electron transport region ETR may be located between the light emitting layer EMIL, and the second electrode EL2. The electron transport region ETR may include at least one of an electron injection layer, an electron transport layer, or a hole blocking layer. The electron transport region ETR may be provided as a common layer to overlap all of the pixel regions PXA-R, PXA-G, and PXA-B and the pixel defining layer PDL that divides the pixel regions PXA-R, PXA-G, and PXA-B. However, the embodiment is not limited thereto. For example, the electron transport region ETR may be patterned so that the electron transport region ETR are separated from each other to respectively correspond to the pixel regions PXA-R, PXA-G, and PXA-B.

The second electrode EL2 may be disposed on the electron transport region ETR. For example, the second electrode EL2 may include a common electrode. For example, the second electrode EL2 may include a cathode or anode, but the embodiment is not limited thereto. For example, when the first electrode EL1 includes an anode, the second electrode EL2 may include a cathode. In addition, when the first electrode EL1 includes a cathode, the second electrode EL2 may include an anode. The second electrode EL2 may include a transmissive electrode, a transflective electrode or a reflective electrode.

The capping layer CPL may be provided on the second electrode EL2. The capping layer CPL may include a multi layer or a single layer. In an embodiment of the present invention, the capping layer CPL may include an organic layer or an inorganic layer. For example, when the capping layer CPL includes an inorganic material, this inorganic material may include an alkali metal compound such as LiF, an alkali earth-metal compound such as MgF₂, or SiON, SiNₓ, SiO_{y}, or the like. For example, when the capping layer CPL includes an organic material, this organic material may include α-NPD, NPB, TPD, m-MTDATA, Alq₃, CuPc, TPD15(N4,N4,N4′N4′-tetra(biphenyl-4-yl)biphenyl-4,4′-diamine), TCTA(4,4′,4″-Tris(carbazol-9-yl)triphenylamine), or the like, or may include an epoxy resin or acrylate such as methacrylate. However, the embodiment is not limited thereto.

Here, the refractive index of the capping layer CPL may be about 1.6 or more. For example, the refractive index of the capping layer CPL may be about 1.6 or more with respect to the light in a wavelength range of about 550 nm to about 660 nm.

In the display module DM according to an embodiment of the present invention, the plurality of light emitting elements ED-1, ED-2, and ED-3 may emit light of different wavelength ranges. For example, in an embodiment of the present invention, the display module DM may include a first light emitting element ED-1 emitting red light, a second light emitting element ED-2 emitting green light, and a third light emitting element ED-3 emitting blue light. For example, in the display device according to an embodiment of the present invention, the red pixel region PXA-R, the green pixel region PXA-G, and the blue pixel region PXA-B may correspond to the first light emitting element ED-1, the second light emitting element ED-2, and the third light emitting element ED-3, respectively.

However, the embodiment is not limited thereto. For example, the first to third light emitting elements ED-1, ED-2, and ED-3 may emit light of the same wavelength range, or at least one of the first to third light emitting elements ED-1, ED-2, and ED-3 may emit light with a wavelength range that is different from the light emitted from the remainder of the first to third light emitting elements ED-1, ED-2, and ED-3. For example, all of the first to third light emitting elements ED-1, ED-2, and ED-3 may emit blue light.

The encapsulation layer TFE may be disposed on the light emitting element ED. The encapsulation layer TFE may be disposed to cover the light emitting element ED. The encapsulation layer TFE may be disposed on the capping layer CPL and partially fill the pixel openings OH.

In FIGS. 3A and 3B, the encapsulation layer TEE is illustrated as having a single layer. However, for example, the encapsulation layer TFE may include at least one organic film or inorganic film or may include both an organic film and an inorganic film. The encapsulation layer TFE may have a thin film encapsulation layer structure that includes at least one organic film and at least one inorganic film. For example, the encapsulation layer TFE may have a structure, in which organic films and inorganic films are alternately and repeatedly stacked on each other, or a structure, in which an inorganic film, an organic film, and an inorganic film are stacked in this order. The encapsulation layer TFE may serve to protect the light emitting elements ED against moisture and/or oxygen and protect the light emitting elements ED against impurities such as dust particles.

The inorganic film included in the encapsulation layer TFE may include, for example, a silicon nitride layer, a silicon oxynitride layer, a silicon oxide layer, a titanium oxide layer, or an aluminum oxide layer, but the embodiment is not particularly limited to the above examples. The organic film included in the encapsulation layer TFE may include an acryl-based organic film, but the embodiment is not particularly limited to the above examples.

The display module DM according to an embodiment of the present inventive concept is illustrated in FIG. 3A may include the color filter layer CFL disposed above the display panel DP. The color filter layer CFL may include a light control layer through which light is selectively transmitted.

The color filter layer CFL may include a filter part CF and a division pattern BM in which division openings OH-BM are formed. The division openings OH-BM may be formed to correspond to the pixel openings OH.

The filter part CF may include a first filter part CF-R, through which first color light is transmitted, a second filter part CF-G, through which second color light is transmitted, and a third filter part CF-B, through which third color light is transmitted. For example, the first filter part CF-R may include a red filter, the second filter part CF-G may include a green filter, and the third filter part CF-B may include a blue filter.

Each of the first to third filter parts CF-R, CF-G, and CF-B may include a polymer photo-sensitive resin and a pigment or dye. The first filter part CF-R may include a red pigment or dye, the second filter part CF-G may include a green pigment or dye, and the third filter part CF-B may include a blue pigment or dye. In addition, the embodiment is not limited thereto, and the third filter part CF-B might not include a pigment or dye. For example, the third filter part CF-B may include a transparent photo-sensitive resin, and the third filter part CF-B may be transparent. When the third filter part CF-B includes a transparent photo-sensitive resin, the light passing through the third filter part CF-B is not limited to the third color light.

The color filter layer CFL may include the division pattern BM. The division pattern BM may be located to correspond to the light blocking region NPXA. For example, the division pattern BM may be disposed in the light blocking region NPXA. The division pattern BM may include an organic light blocking material, which includes a black pigment or a black dye, or an inorganic light blocking material. In addition, the division pattern BM may include a blue filter.

In addition, in an embodiment of the present invention, the color filter layer CFL does not include a separate division pattern BM and may include portions in which the plurality of filter parts CF-R, CF-G, and CF-B overlap each other in the third direction DR3, which is the thickness direction, to correspond to the light blocking region NPXA. The portions, in which the plurality of filter parts CF-R, CF-G, and CF-B overlap each other, may be referred to as a division pattern.

The color filter layer CFL may further include an overcoat layer OC. The overcoat layer OC may cover the filter part CF and the division pattern BM. The overcoat layer OC may overlap the surface of the display element layer DP-ED. For example, the overcoat layer OC may overlap the entire surface of the display element layer DIP-ED. The upper surface of the overcoat layer OC defines the upper surface of the color filter layer CFL and may cover the surface of the display panel DP to protect the display panel DP. For example, the overcoat layer OC may cover an entirety of an upper surface of the display panel DP.

The color filter layer CFL may function as a light control layer that selectively transmits incident light. In an embodiment of the present invention, the color filter layer CFL may include a low reflection layer or a reflection-preventing layer that reduces reflectance due to external light incident from the outside of the display device. In addition, the color filter layer CFL may selectively transmit a portion of the provided light and increase color reproducibility of the display device. As used herein, the “color reproducibility” refers to a range of colors that may be displayed by a display device. For example, the color filter layer CFL may increase the color reproducibility by selectively absorbing or transmitting light in a specific wavelength range.

The light, which passes through the color filter layer CFL and is incident to the display panel DP, may be unpolarized light. The display panel DP may receive unpolarized light from above the color filter layer CFL.

The display device according to an embodiment of the present invention includes the color filter layer, which includes the filter parts for selectively transmitting light, and a low reflection member disposed above the color filter layer, thereby exhibiting an effect of reducing reflected light generated by external light.

In the display module DM according to an embodiment of the present invention, the sensor layer TUT may be located between the display panel DP and the color filter layer CF. The sensor layer TUT may acquire information by an external input so that information (e.g., an image) may be displayed on the display panel DP in response to the external input. The external input may include an input of a user. The input of the user may include various types of external inputs, such as a portion of the user's body, light, heat, a pen, or pressure.

The sensor layer TU may include a sensor base layer BS-TU, a first conductive layer SP1, an inorganic insulating layer IL, a second conductive layer SP2, and an organic insulating layer OL. The first conductive layer SP1 may be disposed on the sensor base layer BS-TU. The inorganic insulating layer IL covers the first conductive layer SP1 and may be disposed on the sensor base layer BS-TU and the first conductive layer SP1. The second conductive layer SP2 may be disposed on the inorganic insulating layer IL. The organic insulating layer OL covers the second conductive layer SP2 and may be disposed on the inorganic insulating layer IL and the second conductive layer SP2.

The sensor base layer BS-TU may be an inorganic layer that includes one of, for example, a silicon nitride, a silicon oxynitride, or a silicon oxide. In addition, the sensor base layer BS-TU may be an organic layer that includes an epoxy resin, an acrylic resin, or an imide-based resin. The sensor base layer BS-TU may have a single-layer structure or a multi-layer structure in which layers are stacked in the third direction DR3. The sensor base layer BS-TU may be disposed on the encapsulation layer TFE. For example, the sensor base layer BS-TU may be disposed directly on the encapsulation layer TFE.

Each of the first conductive layer SP1 and the second conductive layer SP2 may have a single-layer structure or a multi-layer structure in which layers are stacked in the third direction DR3. The conductive layers SP1 and SP2 having a single-layer structure may include a metal layer or a transparent conductive layer. The metal layer may include, for example, molybdenum, silver, titanium, copper, aluminum, or an alloy thereof. The transparent conductive layer may include, for example, transparent conductive oxides, such as an indium tin oxide (ITO), an indium zinc oxide (IZO), a zinc oxide (ZnO), and an indium zinc tin oxide (IZTO). In addition, the transparent conductive layer may include a conductive polymer such as PEDOT, metal nanowire, graphene, and the like.

The conductive layers SP1 and SP2 having a multi-layer structure may include metal layers. The metal layers may include, for example, a three-layer structure of titanium (Ti)/aluminum (Al)/titanium (Ti). The conductive layers SP1 and SP2 having a multi-layer structure may include at least one metal layer and at least one transparent conductive layer.

The inorganic insulating layer IL may include at least one of, for example, an aluminum oxide, a titanium oxide, a silicon oxide, a silicon oxynitride, a zirconium oxide, and/or a hafnium oxide.

A contact hole CN may be formed in the inorganic insulating layer IL. The first conductive layer SP1 and the second conductive layer SP2 may be electrically connected to each other via the contact hole CN. The contact hole CN may be filled with a material of the second conductive layer SP2.

The organic insulating layer OL may cover the inorganic insulating layer IL and the second conductive layer SP2. The organic insulating layer OL may include at least one of, for example, an acryl-based resin, a methacryl-based resin, polyisoprene, a vinyl-based resin, an epoxy-based resin, a urethane-based resin, a cellulose-based resin, a siloxane-based resin, a polyimide-based resin, a polyamide-based resin, and/or a perylene-based resin.

Compared to the display module DM illustrated in FIG. 3A, a display module DM-1 according to an embodiment illustrated in FIG. 3B further includes an inorganic deposition layer INF in a display element layer DP-ED1 In addition, there is a difference in that a light control layer AR different from the color filter layer CFL is provided above a display panel DP in the display module DM-1.

Referring to FIG. 3B, the display element layer DP-ED1 according to an embodiment of the present invention may include the inorganic deposition layer INF disposed on a light emitting element ED. The inorganic deposition layer INF may be disposed on a capping layer CPL. For example, the inorganic deposition layer INF may be disposed directly on the capping layer CPL. The inorganic deposition layer INF may include a layer for preventing external light from being reflected by second electrodes EL2 of light emitting elements ED-1, ED-2, and ED-3. For example, destructive interference occurs between the light reflected from the surface of the inorganic deposition layer INF and the light reflected from the second electrodes EL2, thereby reducing the amount of external light reflected from the surface of the second electrodes EL2. The thicknesses of the inorganic deposition layer INF and the capping layer CPL may be adjusted so that the destructive interference may occur between the light reflected from the surface of the inorganic deposition layer INF and the light reflected from the second electrodes EL2.

The inorganic deposition layer INF may include an inorganic material having a refractive index of about 1.0 or more and a light absorption coefficient of about 0.5 or more. The inorganic deposition layer INF may be formed by a thermal deposition process and include an inorganic material having a melting point of 1000° C. or less. The inorganic deposition layer INF may include, for example, at least one of bismuth (Bi) and/or ytterbium (Yb). A material forming the inorganic deposition layer INF may include bismuth (Bi), ytterbium (Yb), or a mixed deposition material of YbₓBi_{y}. An encapsulation layer TFE may be disposed on at least a portion of the inorganic deposition layer INF. For example, the encapsulation layer TFE may be directly disposed on at least a portion of the inorganic deposition layer INF.

In the display module DM-1 according to an embodiment of the present invention, the light control layer AR may be disposed above the display panel DP. The light control layer AR may increase color reproducibility by absorbing some of light emitted from the display panel DP and transmitting the other of the light. For example, the light control layer AR may increase the color reproducibility by selectively absorbing light in a specific wavelength range.

The light control layer AR may overlap the surface of the display element layer DP-ED1 For example, the light control layer AR may overlap an entirety of an upper surface of the display element layer DP-ED1. The light control layer AR may overlap an entirety of an upper surface of each of a first light emitting element ED-1, a second light emitting element ED-2, and a third light emitting element ED-3. For example, the light control layer AR may overlap the entire surface of each of a first light emitting element ED-1, a second light emitting element ED-2, and a third light emitting element ED-3. The light control layer AR may cover the front surface of the display panel DP and protect the display panel DP. The light, which passes through the light control layer AR and is incident to the display panel DP and a sensor layer TU, may be unpolarized light. The display panel DP and the sensor layer TU may receive unpolarized light from above the light control layer AR.

The light control layer AR may include a division pattern BM and an overcoat layer OC-1. The overcoat layer OC-1 may include an organic material. The overcoat layer OC-1 may include a pigment or dye. The division pattern BM may be located to overlap a light blocking region NPXA. In addition, the division pattern BM may include an organic light blocking material, a black pigment or a black dye, or the like.

The display device including the display module according to an embodiment of the present invention illustrated in FIG. 3B includes the inorganic deposition layer, which induces the destructive interference of light, the light control layer, through which light is selectively transmitted, and a low reflection member disposed above the light control layer, thereby exhibiting an effect of reducing reflected light generated by external light.

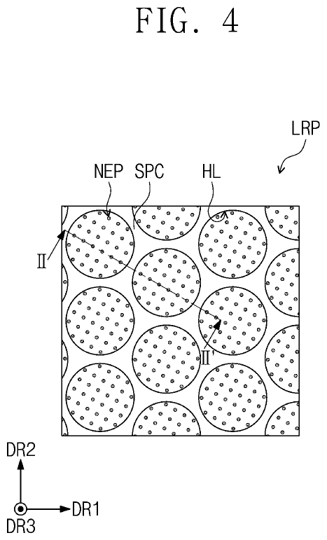

FIG. 4 is a plan view of a low reflection member according to an embodiment of the present invention. FIG. 4 is a plan view of a portion of the low reflection member and may be, for example, a cross-sectional view of a portion corresponding to region “AA” of FIG. 2. FIG. 5A is a cross-sectional view of a low reflection member according to an embodiment of the present invention. FIG. 5A may be a cross-sectional view of a portion corresponding to line II-II′ of FIG. 4.

Referring to FIGS. 4 and 5A, a low reflection member LRP according to an embodiment of the present invention may include a spacer SPC and a nano-protrusion NEP. On a cross-section perpendicular to the upper surface of the window WP (FIG. 2), the shape of the cross-section of the spacer SPC may be different from the shape of the cross-section of the nano-protrusion NEP. For example, the low reflection member LRP according to an embodiment of the present invention may include two or more types of protrusion structures that have different cross-sectional shapes. As used herein, the spacer SPC may be referred to as a support protrusion.

The spacer SPC may include an upper surface US-SP that is substantially a flat surface. The upper surface US-SP of the spacer SPC may be the tipper surface in the display device DD (FIG. 2).

The spacer SPC includes a lower surface DS-SP facing the upper surface US-SP. In an embodiment of the present invention, the width of the lower surface DS-SP is greater than or equal to the width of the upper surface US-SP. Referring to FIG. 5A, etc., in an embodiment of the present invention, a width D_{DS} of the lower surface DS-SP of the spacer SPC in a direction perpendicular to a third direction DR-3, which is the thickness direction, may be greater than a width D_{US} of the upper surface US-SP of the spacer SPC. However, the embodiment is not limited thereto, and the width D_{DS} of the lower surface DS-SP and the width D_{US} of the upper surface US-SP may be substantially equal to each other.

In an embodiment of the present invention, the width D_{US} of the upper surface US-SP of the spacer SPC may be about 30 nanometers (nm) to about 300 nanometers (nm). The spacer SPC may include the flat upper surface US-SP and increase durability of the low reflection member LRP. For example, in an embodiment of the present invention, the spacer SPC includes a flat surface having a width of about 30 nanometers or more, and defines the upper surface of the low reflection member LRP so that the spacer SPC functions as a support. Accordingly, the low reflection member LRP may have excellent wear resistance against external stimuli, etc. In addition, the spacer SPC has the tipper surface having the width of about 300 nanometers or less and optimizes a ratio of the robust structure in the low reflection member LRP. Accordingly, the low reflection member LRP may have good flexibility without deteriorating reflectance reduction characteristics.

A first thickness t_{SP} of the spacer SPC may be about 300 nanometers to about 500 nanometers. The spacer SPC may have a thickness of about 300 nanometers or more, and thus, the low reflection member LRP may have a relatively high rigidity as a support. In addition, the spacer SPC has a thickness of about 500 nanometers or less. Accordingly, it is possible to minimize an increase in the thickness of the display device and impart good flexibility to the low reflection member LRP.

Referring to FIG. 4, in a plan view, the spacer SPC may have a network shape in which a plurality of holes HL are provided. The spacer SPC may have a network structure which is integrally connected to each other while defining the plurality of holes HL. Referring to FIGS. 4 and 5A, the upper surface US-SP of the spacer SPC may correspond to a boundary portion that defines the holes HL when viewed in a plan view.

In the low reflection member LRP according to an embodiment of the present invention, all of the holes HL may have the same shape as each other. For example, each of the holes HL may have a circular shape on a plane defined by first and second directional axes DR1 and DR2. However, the embodiment is not limited thereto, and the shape of the holes HL in a plan view and the size of the holes HL may be variously changed. For example, one low reflection member LRP may include holes having various shapes and/or holes having various sizes.

In the low reflection member LRP according to an embodiment of the present invention illustrated in FIGS. 4 and 5A, a distance of the spacer SPC may be defined as a distance W_{SP} between upper surfaces US-SP of the spacer SPC that define the holes HL. The distance W_{SP} of the spacer SPC may be about 1 micrometer (μm) to about 1000 micrometers (μm). For example, the distance W_{SP} of the spacer SPC may be about 1 micrometer to about 100 micrometers (μm).

In addition, in an embodiment of the present invention, a maximum width W_{SP} of each of the holes HL may be about 1 micrometer to about 1000 micrometers. For example, the maximum width W_{SP} of each of the holes HL may be about 1 micrometer to about 100 micrometers.

In the low reflection member LRP according to an embodiment of the present invention, the distance W_{SP} of the spacer SPC or the maximum width W_{SP} of each of the holes HL is about 1 micrometer to about 100 micrometer, and thus, it is possible to impart excellent durability and good flexibility to the low reflection member while minimizing the effect on the optical properties of the low reflection member that reduces the reflectance.

The low reflection member LRP according to an embodiment of the present invention may include a plurality of nano-protrusions NEP, each of which has a shape different from that of the spacer SPC. Each of the nano-protrusions NEP may have a shape in which a cross-sectional area is gradually reduced in the third direction axis DR3, which is the thickness direction, in a cross-sectional view. Referring to FIG. 5A, in an embodiment of the present invention, the nano-protrusion NEP may have a triangular shape in a cross-sectional view.

In an embodiment of the present invention, as the cross-sectional area of each of the nano-protrusions NEP gradually changes in the thickness direction, the refractive index of the low reflection member LRP including the nano-protrusions NEP may gradually change in the thickness direction. For example, as the cross-sectional area of each of the nano-protrusions NEP in the low reflection member LRP gradually decreases in the third direction axis DR3, which is the thickness direction, a ratio of air filling a space between the nano-protrusions NEP increases. Accordingly, the refractive index is gradually reduced from the lower side to the upper side of the low reflection member LRP. In addition, as the refractive index of the low reflection member LRP gradually changes in the thickness direction, reflection of light in a visible light range may be minimized.

The low reflection member LRP according to an embodiment of the present invention includes the nano-protrusions NEP of which the cross-sectional areas in the thickness direction gradually change. Accordingly, the reflection of light provided to the low reflection member LRP may be minimized, and thus, excellent anti-reflection characteristics may be exhibited.

The plurality of nano-protrusions NEP may be arranged between protrusion portions of the spacer SPC which are spaced apart from each other. For example, in an embodiment, of the present invention, illustrated in FIGS. 4 and 5A, the nano-protrusions NEP may be arranged in the holes HL defined in the spacer SPC.

In the low reflection member LRP according to an embodiment of the present invention, a second thickness t_{NP} of the nano-protrusion NEP may be less than or equal to the first thickness t_{SP} of the spacer SPC. The second thickness t_{NP} of the nano-protrusion NEP may be less than or equal to the first thickness t_{SP} of the spacer SPC and greater than or equal to ½ of the first thickness t_{SP}. The second thickness t_{NP} of the nano-protrusion NEP may be about 300 nanometers to about 500 nanometers. The nano-protrusion NEP may be maintained at the first thickness t_{SP} or less and may be in a thickness range of about 300 nanometers to about 500 nanometers, and thus, the low reflection member LRP may have excellent flexibility and durability.

A width D_{NP} of the lower surface of the nano-protrusion NEP may be about 30 nanometers to about 300 nanometers. A thickness-to-width ratio (t_{NP}/D_{NP}) of each of the nano-protrusions NEP may be about 0.5 or more. For example, the thickness-to-width ratio (t_{NP}/D_{NP}) of the nano-protrusion NEP may be about 1.0 or more. For example, the thickness-to-width ratio (t_{NP}/D_{NP}) of the nano-protrusion NEP may be about 2.0 or more. Each of the nano-protrusions NEP has the thickness-to-width ratio (t_{NP}/D_{NP}) of about 0.5 or more and has a shape in which the cross-sectional area gradually changes in the thickness direction. Accordingly, the low reflection member LRP may have low reflection characteristics.

Upper portions US-NP of the nano-protrusions NEP may be spaced apart from each other. A space distance W_{NP} between the nano-protrusions NEP may be about 30 nanometers to about 300 nanometers. The space distance W_{NP} between the nano-protrusions NEP may represent a distance between the upper portions US-NP of the neighboring nano-protrusions NEP. For example, the space distance W_{NP}, between nano-protrusions NEP may be defined as a distance between upper vertices of neighboring nano-protrusions NEP in a cross-sectional view.

The upper portions US-NP of the plurality of nano-protrusions NEP may be spaced a substantially constant distance apart from each other. Here, the constant distance may be referred to as a pitch between the nano-protrusions NEP.

For example, the low reflection member LRP according to an embodiment of the present invention may include the plurality of nano-protrusions NEP of which the upper portions US-NP are spaced a constant distance apart from each other. However, the embodiment is not limited thereto, and one low reflection member LRP may include nano-protrusions NEP having different space distances. For example, the nano-protrusions NEP may be randomly arranged in the holes HL, of the spacer SPC within a range in which the distances between the upper portions US-NP are about 30 nanometers to about 300 nanometers.

The low reflection member LRP according to an embodiment of the present invention may include two or more types of protrusion structures that have different cross-sectional shapes and, particularly, may include the spacer SPC having the flat upper surface and the nano-protrusions NEP having the cross-sectional areas gradually changing in the thickness direction, thereby exhibiting excellent durability and reliability characteristics while performing a reflection preventing function. In addition, the low reflection member LRP according to an embodiment of the present invention includes the nano-protrusions NEP formed such that the upper portions US-NP thereof are spaced apart from each other. Accordingly, stress during a folding operation is reduced, and thus, excellent folding reliability may be obtained.

FIG. 5B is a cross-sectional view of a low reflection member according to an embodiment of the present invention. FIG. 5B may be a cross-sectional view of a portion corresponding to line II-II′ of FIG. 4. Compared to the embodiment of the low reflection member LRP illustrated in FIG. 5A, a low reflection member LRP-a according to an embodiment illustrated in FIG. 5B may include two types of nano-protrusions NEP-H and NEP-L having different thicknesses.

The low reflection member LRP-a according to an embodiment of the present invention may include a spacer SPC and a plurality of nano-protrusions NEP-H and NEP-L arranged between protrusion portions of the spacer SPC. For example, the low reflection member LRP-a according to an embodiment of the present invention may include a first nano-protrusion NEP-H and a second nano-protrusion NEP-L which are arranged in holes HL of the spacer SPC and have different thicknesses from each other. A thickness t_{NPH} of the first nano-protrusion NEP-H may be greater than a thickness t_{NPL} of the second nano-protrusion NEP-L. Each of the thickness t_{NPH} of the first nano-protrusion NEP-H and the thickness t_{NPL} of the second nano-protrusion NEP-L may be less than or equal to the thickness of the spacer SPC and greater than or equal to half of the thickness of the spacer SPC.

Here, FIG. 5B illustrates an embodiment of the present invention including two types of nano-protrusions which have the same triangular cross-sectional shape but different thicknesses. However, this is merely an example, and the embodiment is not limited thereto. For example, in an embodiment of the present invention, the low reflection member may include two or more types of nano-protrusions, and the two or more types of nano-protrusions may have different shapes or different thicknesses.

Here, FIGS. 4 to 5B illustrate that the spacer SPC and the nano-protrusions NEP, NEP-H, and NEP-L are arranged at substantially constant intervals. However, the embodiment is not limited thereto, and the arrangement intervals may be changed depending on required optical properties.

Each of FIGS. 6A to 6C are perspective views showing three-dimensional shapes of nano-protrusions included in a low reflection member according to an embodiment of the present invention.

Referring to FIG. 6A, a nano-protrusion NEP may have a cone shape. The nano-protrusion NEP having a cone shape may have a triangular shape in a cross-sectional view as illustrated in FIGS. 5A and 5B.

A nano-protrusion NEP-1 according to an embodiment of the present invention may have a polygonal pyramid shape. Referring to FIG. 6B, the nano-protrusion NEP-1 may have a hexagonal pyramid shape. The nano-protrusion NEP-1 having a three-dimensional shape of a polygonal pyramid according to an embodiment of the present invention may have a triangular shape in a cross-sectional view as illustrated in FIGS. 5A and 5B.

The nano-protrusions NEP and NEP-1 according to embodiments illustrated in FIGS. 6A and 6B may have upper sharp vertices. In addition, unlike the drawing, the upper vertices of the nano-protrusions NEP and NEP-1 according to embodiments of the present invention may be manufactured to have curved surfaces.

Referring to FIG. 6C, a nano-protrusion NEP-2 according to an embodiment of the present invention may have a truncated cone shape. The nano-protrusion NEP-2 having a truncated cone shape may have a trapezoidal shape in a cross-sectional view. Unlike those illustrated in FIGS. 6A and 6B, the nano-protrusion NEP-2 according to an embodiment of the present invention includes a flat surface at an upper portion. For example, the area of the flat surface in the upper portion of the nano-protrusion NEP-2 may be significantly smaller than the area of the lower surface of the nano-protrusion NEP-2. Accordingly, the refractive index on the upper side of the nano-protrusion NEP-2 may be substantially similar to the refractive index of air.

Here, FIGS. 6A to 6C illustrate shapes of the nano-protrusions as examples, and the three-dimensional shapes of the nano-protrusions included in the low reflection member according to an embodiment of the present invention is not limited to those illustrated in the drawings. The low reflection member according to an embodiment of the present invention may include nano-protrusions having various three-dimensional shapes as long as the cross-sectional areas of the nano-protrusions are gradually reduced in the thickness direction away from the window.

Referring back to FIG. 5A, the low reflection member LRP according to an embodiment of the present invention may further include a base part BSP. The low reflection member LRP may include the base part BSP, which is located adjacent to the window WP (FIG. 2), and the spacer SPC and the nano-protrusion NEP, which are arranged on the base part BSP.

The low reflection member LRP according to an embodiment of the present invention may include a composite material that includes organic resin and silicon oxide (SiOₓ). The organic resin may include at least one of, for example, acrylate-based resin, urethane-based resin, or epoxy-based resin.

The refractive index of the composite material may vary depending on the type of organic resin used, the type of silicon oxide used, the weight ratio of the organic resin and the silicon oxide, or the like. The refractive index of the composite material forming the low reflection member LRP may be about 1.5 to about 1.9 at a wavelength of about 550 nm. For example, the refractive index of the composite material forming the low reflection member LRP may be about 1.5 to about 1.6 at a wavelength of about 550 nm.

The low reflection member LRP according to an embodiment of the present invention may exhibit different reflectance characteristics depending on the refractive indexes of materials used to manufacture the low reflection member. In addition, in the low reflection member LRP according to an embodiment of the present invention, a ratio of an area occupied by the spacer SPC may be changed depending on the refractive indexes of materials used to manufacture the low reflection member LRP. As used herein, the area ratio of the spacer SPC is defined as a ratio of the area of the entire upper surface of the spacer SPC to the area of the entire plane of the low reflection member parallel to the plane defined by the first and second direction axes DR1 and DR2.

In an embodiment of the present invention, as the refractive index of a material used to manufacture the low reflection member LRP increases, a ratio of an area occupied by the spacer SPC in the low reflection member LRP may decrease. For example, as the refractive index of the material used to manufacture the low reflection member increases, the ratio of the area occupied by the spacer SPC may decrease, and the ratio of the area in which the nano-protrusions NEP are arranged may increase.

In an embodiment of the present invention, when the reflectance of the low reflection member LRP is controlled to about 3% or less, the reflection due to external light is reduced, and the display device may exhibit excellent display quality. In order for the low reflection member LRP to satisfy reflectance characteristics of about 3% or less, the area ratio of the spacer may be adjusted according to the type of material used to manufacture the low reflection member LRP.

Table 1 below shows the area ratio of the spacer according to the refractive index of the low reflection member LRP. In Table 1, the refractive index corresponds to the refractive index of the composite material used to manufacture the low reflection member LRP. The refractive index values in Table 1 correspond to the refractive index values at about 550 nm.

In addition, the area ratio of the spacer corresponds to the maximum area ratio value of the spacer that satisfies the range of about 3% or less in reflectance. That is, in Examples 1 to 4 shown in Table 1, the area of the spacer corresponds to the maximum value among the area ratios of the upper surface of the spacer on the basis of 100% of the area of the low reflection member LRP.

The reflectance in Table 1 corresponds to the value calculated by Equation (1) below.

$$Reflectance ( \% ) = ( {R}_{X} \times \frac{X}{100} ) + ( 1 \times ( 1 - \frac{X}{100} ) ) \qquad ( 1 )$$

In Equation (1), X is the area ratio of the spacer, and Rx corresponds to a reference reflectance value calculated by Equation (2) below. The reference reflectance calculated by Equation (2) corresponds to a reflectance value when the low reflection member is made of 100% of the spacer.

$$Reference Reflectance ( {R}_{X} ) ( \% ) = {\vert \frac{{n}_{A} - {n}_{X}}{{n}_{A} + {n}_{X}} \vert}^{2} ) \qquad ( 2 )$$

In Equation (2), n_{A} is the refractive index of air, and n_{A} corresponds to LO in calculation of reference reflectance. In Equation 2, n_{X} corresponds to the refractive index value of the material that forms the low reflection member.

TABLE 1

| | | Reference | | |
|---|---|---|---|---|
| | Refractive | reflectance | Area ratio (%) | Reflectance |
| Classification | index | (%) | of spacer | (%) |
| Example 1 | 1.5 | 4.00 | 65 | 2.95 |
| Example 2 | 1.6 | 5.30 | 45 | 2.93 |
| Example 3 | 1.7 | 6.73 | 35 | 3.00 |
| Example 4 | 1.8 | 8.16 | 25 | 2.79 |
| Example 5 | 1.9 | 9.63 | 20 | 2.73 |

Referring to Examples 1 to 5, to satisfy the reflectance characteristics for the low reflection member according to an embodiment of the present invention, it may be seen that as the refractive index of the material forming the low reflection member increases, the area ratio of the spacer in the low reflection member should decrease.

Here, in each of Examples 1 to 5, the minimum value of the area ratios of the spacer may be about 10% or more. That is, Examples include the spacer in an area ratio of about 10% or more, and thus, the spacer functions as a support portion. Accordingly, the low reflection member may have excellent durability while maintaining low reflection characteristics.

Referring to Table 1, when the refractive index of the material for manufacturing the low reflection member is about 1.5 to about 1.9, the area ratio of the spacer is about 10% or more on the basis of 100% of the area of the low reflection member LRP. In addition, the maximum value of the area ratio of the spacer may be about 65% to about 20% according to the refractive indexes.

For example, when the refractive index of the composite material for manufacturing the low reflection member LRP is about 1.5 to about 1.6, the area of the tipper surface of the spacer may be about 10% to about 45% on the basis of 100% of the total area of the low reflection member LRP in a plan view. For example, when the refractive index of the composite material is about 1.5, the area of the upper surface of the spacer may be about 10% to about 65% on the basis of 100% of the total area of the low reflection member. In addition, when the refractive index of the composite material is about 16, the area of the upper surface of the spacer may be about 10% to about 45% on the basis of 100% of the total area of the low reflection member LRP.

The low reflection member according to an embodiment of the present invention includes the spacer formed to have the area ratios within the above-described ranges according to the refractive index of the composite material, and may simultaneously exhibit excellent low reflection characteristics and durability characteristics.

In addition, the low reflection member LRP may further include an antifouling additive in addition to the composite material including the organic resin and the silicon oxide. The antifouling additive may be provided while being dispersed throughout the low reflection member LRP. For example, the antifouling additive may be provided relatively adjacent to the surface of the low reflection member LRP.

The antifouling additive may include a fluorine-based additive or a silicone-based additive. The low reflection member LRP formed to include an antifouling additive may exhibit liquid-repellent characteristics. The low reflection member LRP formed of a composite material including an antifouling additive may exhibit a contact angle of about 95° or more with respect to deionized water.

The low reflection member LRP according to an embodiment of the present invention may be manufactured by a nano-imprinting method. A composite material is applied on the upper surface of the window WP, and a replica, which is manufactured to form the spacer SPC and the nano-protrusion NEP of the low reflection member LRP, is disposed on the applied composite material layer. Accordingly, the low reflection member LRP may be manufactured by an imprinting method, After the imprinting, the composite material layer may be cured by ultraviolet light or the like.

In addition, unlike the above method, the low reflection member LRP might not be directly formed on the window, but may be manufactured in a separate process and provided on the window WP (FIG. 2). For example, a composite material is applied on a replica that is manufactured to form the spacer SPC and the nano-protrusion NEP of the low reflection member LRP and then cured by ultraviolet light. Subsequently, the replica may be removed to manufacture the low reflection member LRP. The manufactured low reflection member LRP may be attached to the upper surface of the window WP (FIG. 2) For example, an adhesive layer may be disposed between the low reflection member LRP and the window WP (FIG. 2) according to an embodiment of the present invention, and thus, the low reflection member LRP may be coupled to the window WP (FIG. 2). Here, the adhesive layer may include an optically clear adhesive layer.

The low reflection member LRP according to an embodiment of the present invention may include the spacer SPC having the flat upper surface and the nano-protrusions NEP having the cross-sectional areas gradually changing in the thickness direction, thereby simultaneously exhibiting excellent rigidity and durability while having low reflection characteristics that reduce reflection of external light. The upper portions of the nano-protrusions NEP are spaced apart from each other, and thus, the low reflection member LRP may exhibit excellent flexibility. In addition, the arrangement ratio of the spacer SPC is optimized according to the refractive index of the material used to form the low reflection member LRP, thus making it possible to simultaneously exhibit excellent low reflection characteristics and excellent durability characteristics.

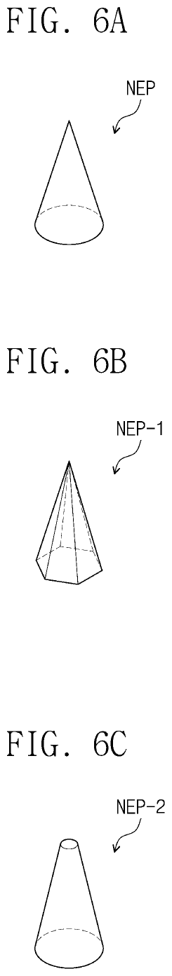

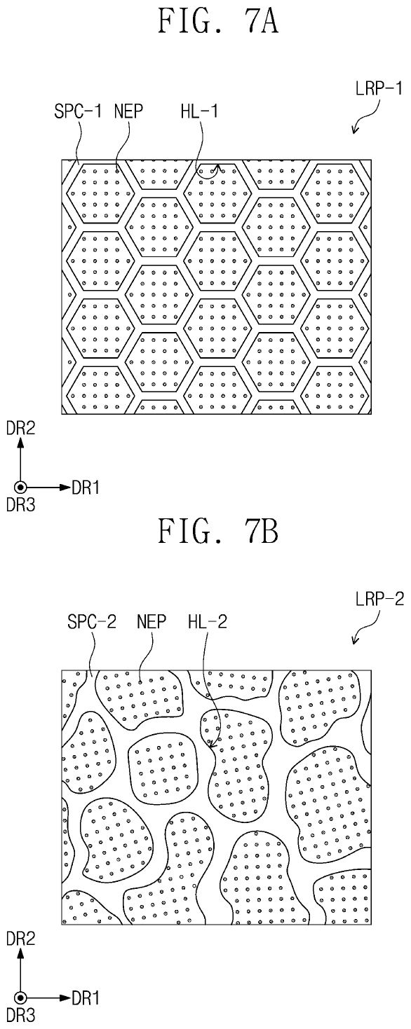

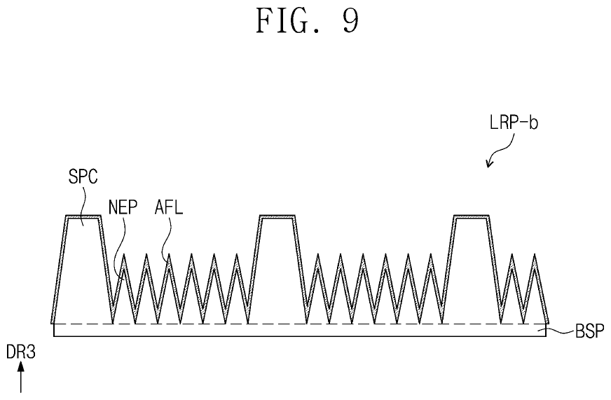

Hereinafter, a low reflection member LRP according to an embodiment of the present invention is described with reference to FIGS. 7A to 9, etc. When describing a low reflection member LRP with reference to FIGS. 7A and 9, repeated descriptions as those given with reference to FIGS. 1 to 6C may be omitted or briefly discussed, and their differences are mainly described. A low reflection member according to an embodiment of the present invention described with reference to FIGS. 7A to 9 may be included as the low reflection member in the display device illustrated in FIG. 2.

Each of FIGS. 7A and 7B is a plan view showing a low reflection member according to an embodiment of the present invention, Each of FIGS. 7A and 7B may show an embodiment of a portion corresponding to region “AA” of FIG. 2.

Referring to FIGS. 7A, a low reflection member LRP-1 according to an embodiment of the present invention may include a spacer SPC-1 and a nano-protrusion NEP. In an embodiment of the present invention, the spacer SPC-1 may have a network shape in which a plurality of holes HL-1 are provided. A plurality of nano-protrusions NEP may be arranged in each of the holes HL-1. Each of the holes HL-1 of the low reflection member LRP-1 according to an embodiment of the present invention may have a hexagonal shape in a plan view. However, the embodiment is not limited thereto, and each of the holes HL-1 may have various shapes, such as a circular shape, an elliptical shape, and a polygonal shape in a plan view.

The spacer SPC-1 may have a network structure that has a honeycomb shape, a spider web shape, or a shape in which holes are defined by closed curves when viewed in a plan view.

In addition, the descriptions with reference to FIGS. 5A to 6C are applied, in the same manner, to the widths of the holes HL-1 defined in the spacer SPC-1, the thickness of the spacer SPC-1, and the thicknesses and shapes of the nano-protrusions NEP.

Referring to FIGS. 7B, a low reflection member LRP-2 according to an embodiment of the present invention may include a spacer SPC-2 and a nano-protrusion NEP In an embodiment of the present invention, the spacer SPC-2 may have a network shape in which a plurality of holes HL-2 are defined. Each of the holes HL-2 of the low reflection member LRP-2 according to an embodiment of the present invention may have an irregular shape.

For example, the holes HL-2 of the low reflection member LRP-2 according to an embodiment of the present invention have irregularly random shapes in a plan view, and a plurality of nano-protrusions NEP may be arranged in the holes HL-2. For example, the holes HL-2 have different shapes from each other.

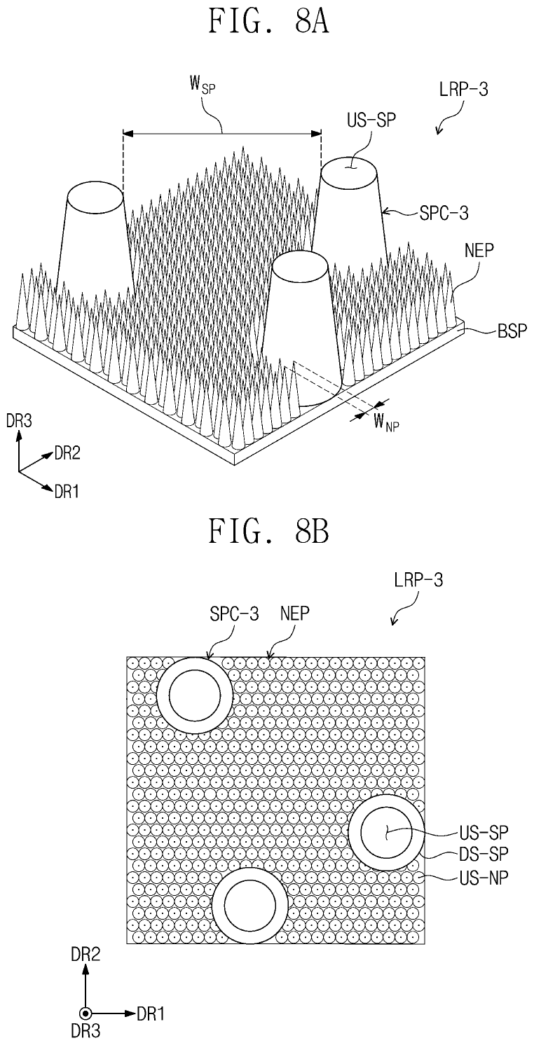

FIG. 8A is a perspective view of a low reflection member according to an embodiment of the present invention. FIG. 8B is a plan view of a low reflection member according to an embodiment of the present invention. FIG. 8B is a plan view of a low reflection member LRP-3 illustrated in FIG. 8A.

Referring to FIGS. 8A and 8B, the Low reflection member LRP-3 according to an embodiment of the present invention may include a spacer SPC-3 and a nano-protrusion NEP. In the low reflection member LRP-3 according to an embodiment of the present invention, the spacer SPC-3 may include a plurality of support protrusions spaced apart from each other. For example, in the low reflection member LRP-3 according to an embodiment of the present invention, the spacer may be referred to as a support protrusion.

The low reflection member LRP-3 according to an embodiment of the present invention may include a plurality of support protrusions SPC-3 spaced apart from each other and a plurality of nano-protrusions NEP arranged between the spaced support protrusions SPC-3. Each of the support protrusions SPC-3 may include a flat upper surface US-SP. Each of the plurality of nano-protrusions NEP may have a shape in which the cross-sectional area gradually decreases in the thickness direction as illustrated in FIGS. 5A and 53.

Referring to FIG. 8A, in an embodiment of the present invention, the nano-protrusions NEP and the support protrusions SPC-3 may be arranged on a base part BSP. For example, the nano-protrusions NEP and the support protrusions SPC-3 may be randomly arranged on a base part BSP. However, the embodiment is not limited thereto, and each of the nano-protrusions NEP and the support protrusions SPC-3 may be arranged in a regular arrangement and at regular intervals.

In an embodiment of the present invention illustrated in FIGS. 8A and 8B, a space distance W_{NP} between the nano-protrusions NEP may be about 30 nanometers to about 300 nanometers. Here, the space distance W_{NP} between the nano-protrusions NEP may represent a distance between upper portions US-NP of the neighboring nano-protrusions NEP. For example, in an embodiment of the present invention, the space distance W_{NP} between the nano-protrusions NEP may represent a distance between the upper vertices of the neighboring nano-protrusions NEP.

FIGS. 8A and 8B illustrate that the nano-protrusions NEP are arranged adjacent to each other as much as possible so that the upper surface of the base part BSP is minimally exposed. However, in an embodiment of the present invention, when the nano-protrusions NEP are spaced apart from each other, the upper surface of the base part BSP may be exposed.

When the nano-protrusions NEP are spaced apart from each other and arranged on the base part BSP so that the upper surface of the base part BSP is exposed, the space distance W_{NP} between the neighboring nano-protrusions NEP at the bottom may be about 50 nm. Here, the space distance W_{NP} between the nano-protrusions NEP at the bottom may be defined as the maximum space distance W_{NP} between the lower surfaces of the nano-protrusions NEP that contact the base part BSP. For example, when the upper surface of the base part BSP is exposed because the nano-protrusions NEP are spaced apart from each other, the maximum width, in one direction, of the upper surface of a portion of the base BSP that may be exposed between the nano-protrusions NEP may be about 50 nm or less.

In addition, in an embodiment of the present invention, all of the nano-protrusions NEP formed to be distinct from each other may cover the entire upper surface of the base part BSP. For example, the nano-protrusions NEP may be arranged so that the lower surfaces thereof are adjacent and in contact with each other. Here, the nano-protrusions NEP and the support protrusions SPC-3 are arranged on the upper surface of the base part BSP, and the upper surface of the base part BSP might not be exposed. To prevent the upper surface of the base part BSP from being exposed, the shapes of the support protrusions SPC-3 and the nano-protrusions NEP may be different from those illustrated in FIGS. 8A and 8B. For example, the lower surfaces of the support protrusions SPC-3 and the nano-protrusions NEP may have polygonal or amorphous shapes.

FIGS. 8A and 8B show, as an example, an embodiment of the low reflection member LRP-3 that includes the support protrusions SPC-3 spaced apart from each other as spacers. In the low reflection member LRP-3 according to an embodiment of the present invention, the arrangement form and the arrangement interval of the nano-protrusions NEP and the support protrusions SPC-3 and the area ratio of the two types of protrusions may be changed according to the reflectance and durability characteristics required in the low reflection member LRP-3. For example, the ratio of the support protrusions SPC-3 may be relatively increased to increase durability and reliability of the low reflection member LRP-3, and the ratio of the nano-protrusions NEP may be relatively increased for low reflection characteristics.

FIG. 9 is a cross-sectional view of a low reflection member according to an embodiment of the present invention Referring to FIG. 9, a low reflection member LRP-b according to an embodiment of the present invention may further include a cover layer AFL, compared to the low reflection member LRP illustrated in FIG. 5A, etc.

The cover layer AFL may cover the nano-protrusion NEP and the spacer SPC. For example, the cover layer AFL may cover the entirety of the nano-protrusion NEP and the spacer SPC. The cover layer AFL may include an antifouling additive. The cover layer AFL may include a fluorine-based additive or a silicone-based additive. The cover layer AFL may have the thickness of about 20 nanometers or less.

The cover layer AFL may increase liquid-repellent characteristics of the low reflection member LRP-b. A contact angle of deionized water with respect to the low reflection member LRP-b including the cover layer AFL may be about 95 degrees or more. For example, a contact angle of deionized water with respect to the low reflection member LRP-b including the cover layer AFL may be about 110 degrees or more.

For example, the low reflection member LRP-b according to the embodiment illustrated in FIG. 9 includes the spacer SPC and the nano-protrusion NEP and further includes the cover layer AFL, thus making it possible to exhibit excellent low reflection characteristics and at the same time have excellent durability and antifouling characteristics.

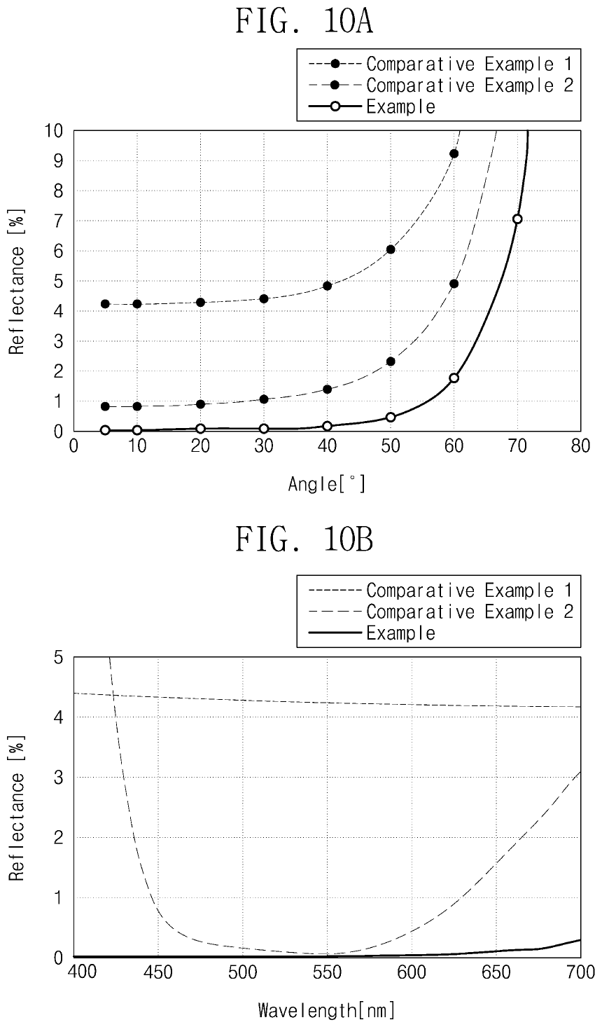

Each of FIGS. 10A and 10B is a graph showing reflectance characteristics for Example and Comparative Example. FIG. 10A is a graph showing a change in reflectance according to a viewing angle, and FIG. 10B is a graph showing a change in reflectance according to a wavelength of incident light. FIG. 10A shows a change in reflectance when light having a wavelength of about 550 nm is provided. In FIGS. 10A and 10B, reflectance corresponds to specular component include (SCI) reflectance.

In FIGS. 10A and 10B, Comparative Example 1 relates to a window including a glass substrate, and Comparative Example 2 relates to a structure in which a low reflection layer is stacked on the window as an anti-reflection structure. In Comparative Example 2, the low reflection layer does not include nanostructures. In Comparative Example 2, the low reflection layer may have a structure in which Nb₂O₅/SiOₓ are repeatedly stacked. In addition, Example relates to a structure in which the low reflection member according to an embodiment of the present invention described with reference to FIGS. 4 and 5A is disposed on the window.

Referring to FIG. 10A, it may be seen that Example exhibits low reflectance values over the entire range of viewing angles compared to Comparative Examples 1 and 2. For example, it may be seen that Example shows a reflectance value of about 3% or less up to a viewing angle of about 60 degrees, and thus, exhibits improved anti-reflection characteristics over a wide viewing angle range compared to Comparative Examples 1 and 2. Accordingly, the display device including the low reflection member according to Example may have low reflection characteristics over a wide viewing angle range and exhibit excellent display quality.

Referring to FIG. 10B, compared to Comparative Example 1 and Comparative Example 2, Example exhibits low reflectance characteristics over the entire range of the visible light region of about 400 nm to about 700 nm. In Example, the deviation of the reflectance in the entire visible light region may be about 1% or less. Accordingly, the display device including the low reflection member according to Example has low reflection characteristics with respect to all light in the visible light region and has a small reflectance deviation, thereby exhibiting excellent display quality.

Table 2 shows evaluation results of material properties for Example corresponding to the display device according to the embodiment and for Comparative Example in which a display device does not include a low reflection member. In Table 2, the display device of Comparative Example includes, on the window, a protective film instead of a low reflection member. The display module used in the evaluation shown in Table 2 may have a structure illustrate in FIG. 3A.

In Table 2, the reflectance corresponds to the SCI reflectance, and the initial contact angle is a contact angle for deionized water before the reliability test is performed. Pencil hardness is a value obtained by measuring the hardness of the uppermost surface of the display device, and adhesion force was evaluated by the degree of damage to the uppermost layer when a tape is attached to and then detached from the uppermost surface of the display device.

Wear resistance and chemical resistance were evaluated by repeated rubbing with a Minoan eraser for wear test at a speed of about 50 rpm under a load of about 1 kgf. In Table 2, the wear resistance is represented by the maximum number of repetitions of rubbing at which the contact angle with respect to deionized water is maintained at about 95 degrees or more after rubbing with the eraser under the above conditions. The chemical resistance is represented by the maximum number of repetitions of rubbing at which the contact angle with respect to deionized water is maintained at about 95 degrees or more after applying ethanol to a surface.

In Table 2, folding reliability corresponds to visually evaluating appearance quality after each of evaluation conditions. T1 test for the folding reliability evaluates the maximum number of folding repetitions at which the appearance quality is maintained well when the display device is repeatedly folded under about 60° C. and about 93% humidity conditions. T2 test evaluates the maximum number of folding repetitions at which the appearance quality is maintained well when the display device is repeatedly folded under a condition of about −20° C.

T3 test evaluates the maximum number of cycle repetitions at which the appearance quality is maintained well when a cycle of repeating about 30K folding under about −20° C. condition and then maintaining the folded state for about 12 hours is repeated. The T4 test evaluates the maximum folding time at which the appearance quality is maintained well when the folded state is maintained at −20° C., In addition, in the results of Table 2, “K” corresponds to 1000 times. For example, 6K corresponds to 6000 times.

TABLE 2

| | | Comparative | |
|---|---|---|---|
| Items | | Example | Example |
| Reflectance (%) | | 6.05 | 3% or less |
| Initial contact angle (°) | | >110 | >110 |
| Pencil hardness | | >4F | >4F |
| Adhesion force | | >4B | >4B |
| Wear resistance | | >6K | >6K |
| Chemical resistance | | >1.5K | >1.5K |
| Folding | T1 (60° C./93%) | 70K | >70K |
| Reliability | T2 (−20° C.) | 30K | >30K |
| | T3 (maintaining folding for 12 | 10 times | 10 times |
| | hours after −20° C., 30K) | | |
| | T4 (70° C., maintaining | 240 hours | 240 hours |
| | folding) | | |

Referring to the results of Table 2, the display device according to Example exhibits pencil hardness, adhesion force, wear resistance, and chemical resistance which are equal to or higher than those of Comparative Example related to a display device according to the related art that does not include a low reflection member. Therefore, it may be said that the display device according to Example exhibits excellent durability and reliability. For example, it may be seen that Example exhibits excellent durability and reliability characteristics while having a reflectance of about 3% or less.

In addition, it may be seen that Example exhibits excellent folding reliability equal to or higher than that of Comparative Example while having a reflectance of about 3% or less.

For example, referring to the results of Table 2, it may be seen that the display device according to an embodiment of the present invention including the low reflection member according to an embodiment of the present invention maintains low reflection characteristics of reducing reflectance due to external light and at the same time exhibits excellent durability, reliability, and folding characteristics.

The display device according to an embodiment of the present invention includes the low reflection member that includes the spacer SPC having the flat upper surface and the nano-protrusions NEP having the cross-sectional areas gradually changing in the thickness direction, thereby simultaneously exhibiting excellent rigidity and durability while having excellent low reflection characteristics. In addition, the display device according to an embodiment of the present invention may include the low reflection member, in which the upper portions of the nano-protrusions NEP are spaced apart from each other, and thus, may exhibit excellent folding reliability.

The display device according to an embodiment of the present invention includes a low reflection member that includes at least two types of nanostructures having different shapes and sizes, and thus, may simultaneously exhibit the low reflectance of external light and increased reliability.

While the present invention has been described with reference to embodiments thereof, it will be understood by those of ordinary skill in the art that various changes in form and details may be made thereto without departing from the spirit and scope of the present invention.

What is claimed is:

1. A display device comprising:
a display module;
a window disposed on the display module; and
a low reflection member disposed on the window and comprising a spacer and a nano-protrusion which have different cross-sectional shapes from each other,
wherein a first thickness of the spacer is greater than or equal to a second thickness of the nano-protrusion,
an upper surface of the spacer has a substantially flat surface that is parallel to an upper surface of the window, and
a width of the nano-protrusion gradually reduces as a distance from the window increases.

2. The display device of claim 1, wherein, in a plan view parallel to the window, the spacer has an integrated shape in which a plurality of holes are provided.

3. The display device of claim 2, wherein the maximum width of each of the holes is about 1 micrometer (μm) to about 1000 micrometers (μm).

4. The display device of claim 2, wherein a plurality of nano-protrusions are arranged in each of the holes, and the plurality of nano-protrusions includes the nano-protrusion, and
wherein upper portions of the plurality of nano-protrusions are spaced apart from each other.

5. The display device of claim 4, wherein each of the holes has a circular, elliptical, or polygonal shape.

6. The display device of claim 4, wherein distances between the upper portions of the plurality of nano-protrusions are about 30 nanometers (nm) to about 300 nanometers (nm).

7. The display device of claim 1, wherein the spacer comprises a plurality of support protrusions spaced apart from each other, and
a plurality of nano-protrusions are arranged between the support protrusions.

8. The display device of claim 7, wherein distances between the support protrusions are about 1 μm to about 1000 μm, and
distances between the plurality of nano-protrusions are about 0.03 pam to about 0.3 μm.

9. The display device of claim 1, wherein the nano-protrusion has a cone shape, a polygonal pyramid shape having a polygonal lower surface, or a truncated cone shape.

10. The display device of claim 1, wherein the low reflection member further comprises a base part disposed on the window.

11. The display device of claim 1, wherein the low reflection member comprises a composite material that has organic resin and silicon oxide (SiOₓ),
wherein the organic resin comprises at least one of acrylate-based resin, urethane-based resin, or epoxy-based resin.

12. The display device of claim 11, wherein as a refractive index of the composite material increases, an area ratio of the upper surface of the spacer in the low reflection member is reduced.

13. The display device of claim 12, wherein the refractive index of the composite material is about 1.5 to about 1.6, and
an area of the upper surface of the spacer is about 10% to about 45% on the basis of about 100% of the total area of the low reflection member.

14. The display device of claim 11, wherein the low reflection member further comprises an antifouling additive that comprises a fluorine-based additive or a silicone-based additive.

15. The display device of claim 14, wherein the low reflection member has a contact angle of about 95 degrees or more with respect to deionized water.

16. The display device of claim 14, wherein the low reflection member further comprises a cover layer covering the spacer and the nano-protrusion and comprising the antifouling additive.

17. The display device of claim 1, wherein the display module comprises:
a display element layer comprising a pixel defining layer, in which a plurality of pixel openings are provided, and light emitting elements, which comprise light emitting layers respectively arranged in the pixel openings;
a sensor layer disposed on the display element layer and comprising a conductive layer and an insulating layer; and
a color filter layer disposed on the sensor layer and comprising a division pattern, in which division openings respectively corresponding to the pixel openings are provided, and filter parts, which are respectively arranged to overlap the division openings.

18. The display device of claim 1, wherein the display module comprises:
a display element layer comprising a pixel defining layer, in which a plurality of pixel openings are provided, light emitting elements, which comprise light emitting layers respectively arranged in the pixel openings, and an inorganic deposition layer, which is disposed on the light emitting elements;
a sensor layer disposed on the display element layer and comprising a conductive layer and an insulating layer; and
a light control layer disposed on the sensor layer and comprising pigment or dye.

19. The display device of claim 1, wherein the low reflection member is disposed directly on the window.

20. The display device of claim 1, further comprising a folding region, a first non-folding region, and a second non-folding region, wherein the folding region is disposed between the first non-folding region and the second non-folding region.

21. A display device comprising:
a display module;
a window disposed on the display module; and
a low reflection member disposed on the window and comprising a spacer, in which a plurality of holes are provided, and a plurality of nano-protrusions, which are respectively arranged in the holes,
wherein an upper surface of the spacer, which is spaced apart from the window, has a substantially flat surface,
a width of each of the nano-protrusions is gradually reduced in a direction away from the window, and
the spacer has a first thickness, and each of the nano-protrusions has a second thickness that is greater than or equal to half of the first thickness and less than or equal to the first thickness.

22. The display device of claim 21, wherein the maximum width of each of the holes is about 1 micrometer (μm) to about 1000 micrometers (μm).

23. The display device of claim 22, wherein each of the holes has a circular, elliptical, or polygonal shape.

24. The display device of claim 21, wherein tipper portions of the nano-protrusions are spaced apart from each other at a distance of about 30 nanometers (nm) to about 300 nanometers (nm).

25. The display device of claim 21, wherein the low reflection member comprises a composite material that has organic resin and silicon oxide (SiOₓ),
wherein the organic resin comprises at least one of acrylate-based resin, urethane-based resin, or epoxy-based resin.

26. The display device of claim 25, wherein as a refractive index of the composite material increases, an area ratio of the upper surface of the spacer in the low reflection member is reduced.

27. The display device of claim 26, wherein the refractive index of the composite material is about 1.5 to about 1.6, and
an area of the upper surface of the spacer is about 10% to about 45% on the basis of about 100% of the total area of the low reflection member.
